(19) United States
(12) Patent Application Publication
(10) Pub. No.: US 2026/0050009 A1
(43) Pub. Date: Feb. 19, 2026

(54) PROBE CARDS AND METHODS RELATED THERETO

(71) Applicant: Adeia Semiconductor Bonding Technologies Inc., San Jose, CA (US)

(72) Inventors: Belgacem Haba, Saratoga, CA (US); Gaius Gillman Fountain, Jr., Youngsville, NC (US); Cyprian Emeka Uzoh, San Jose, CA (US); Thomas Workman, San Jose, CA (US)

(21) Appl. No.: 18/960,676

(22) Filed: Nov. 26, 2024

Related U.S. Application Data
(60) Provisional application No. 63/684,149, filed on Aug. 16, 2024.

(51) Int. Cl. G01R 1/073; G01R 1/067

(52) U.S. Cl. CPC G01R 1/07342; G01R 1/06744; G01R 1/06761

(57) ABSTRACT

Embodiments herein provide for probe cards and methods related thereto. A probe card comprises a probe and a substrate. The probe comprises a probe stand, a probe beam, and a probe tip. The probe tip and probe stand extend in a first direction, and the probe beam extends in a second direction different than the first direction. The substrate comprises a conductive feature disposed in a material layer. The probe stand of the probe is directly bonded to the conductive feature of the substrate via direct metal bonds.

### CROSS-REFERENCE TO RELATED APPLICATION

This application claims the benefit of U.S. Provisional Ser. No. 63/684,149, filed Aug. 16, 2024, which is hereby incorporated by reference herein in its entirety.

### FIELD

The present disclosure relates to testing of semiconductor devices, and in particular, probe cards and methods related thereto.

### BACKGROUND

As pitch of pads on semiconductor devices (e.g., chips) get smaller, testing the semiconductor devices becomes more difficult. Accordingly, there exists a need for improved (e.g., fine pitch, cost effective) systems and methods for testing semiconductor devices.

### SUMMARY

Embodiments herein provide for probes, probe structures, and/or probe cards and methods of forming the same. Advantageously, methods and probe structures described herein may provide for probe cards with fine pitch (e.g., less than about 10 μm, less than about 20 μm, less than about 30 μm, less than about 40 μm, etc.) and may enable durable and reliable performance.

One general aspect includes a probe card comprising a probe and a substrate. The probe includes a probe tip, a probe beam, and a probe stand. The probe tip extends in a first direction, and the probe beam extends in a second direction different than (e.g., orthogonal to or not orthogonal to) the first direction. The probe stand extends in the first direction. The substrate comprises a conductive feature disposed in a material layer, and the probe stand is directly bonded to the conductive feature of the substrate via direct metal bonds. The substrate may be an interposer, a translator, or a board (e.g., PCB board).

In some embodiments, the probe tip and the probe beam comprise a first metal fill layer. The probe stand may comprise a second metal fill layer. The probe beam may be directly bonded to the probe stand via direct metal bonds. The probe stand may be disposed in a silicon structure or an oxide structure.

In some embodiments, the probe tip comprises a first metal fill layer, and the probe beam and the probe stand comprises a second metal fill layer. The probe tip may be directly bonded to the probe beam via direct metal bonds.

In some embodiments, the probe card comprises a plurality of probes. A length of each probe beam of the plurality of probes may be greater than a pitch of the plurality of probes in the probe card. Each probe beam may be in a spiral shape from a top down view.

In some embodiments, the probe stand is disposed in a patterned dielectric layer (e.g., inorganic or organic dielectric layer or combination thereof), and an opening in the patterned dielectric layer defines a cavity that the probe beam can enter when deflected. In some embodiments, the probe beam is disposed in a same plane as a first patterned dielectric layer, the probe stand is disposed in a second patterned dielectric layer, and an opening in the first patterned dielectric layer and the second patterned dielectric layer defines a cavity that the probe beam can enter when deflected. In some embodiments, the patterned dielectric layer may be a patterned oxide layer, and the second patterned dielectric layer is a second patterned oxide layer. In some embodiments, the substrate comprises a cavity that the probe beam can enter when deflected.

In some embodiments, the probe tip includes a probe tip spacer extending a distance of the probe tip to the probe beam. The probe tip spacer may be less than about 10 microns in height.

In some embodiments, the probe card comprises a plurality of probes comprising first probes and second probes. The probe tips of the first probes and the probe tips of the second probes may be substantially co-planar in a first plane. The probe beams of the first probes may be substantially co-planar in a second plane different than the first plane, and the probe beams of the second probes may be substantially co-planar in a third plane different than the first plane and the second plane.

In some embodiments, the probe card comprises a plurality of probes where the plurality of probes are substantially co-planar. The pitch of the plurality of probes may be less than about 40 microns, less than about 30 microns, less than about 20 microns, or less than about 10 microns.

In some embodiments, the probe tip comprises a metal fill material and a metal plating material covering the metal fill material. In some embodiments, the probe tip and the probe beam comprise a metal fill material and a metal plating material covering the metal fill material. In some embodiments, the probe beam comprises a metal fill material and a metal plating material covering the metal fill material. In some embodiments, the probe tip or probe beam or both comprises a 3D printed metal, metal alloy or metal composite. In some embodiments, the probe tip or probe beam or both comprises a 3D printed layer and a metal plating material.

A second general aspect includes a method of fabricating a probe card. The method comprises providing one or more probes, each probe comprising a probe stand, a probe beam, and a probe tip. The method further comprises providing a substrate comprising one or more conductive features disposed in a material layer. The method further comprises directly bonding each probe stand to a respective conductive feature. In some embodiments, the substrate is an interposer, a translator, or a board (e.g., PCB board).

A third general aspect includes a method of fabricating a probe card including etching a plurality of first openings and a plurality of second openings in a first substrate. The plurality of first openings extends in a first direction and the plurality of second openings extend in a second direction different than (e.g., orthogonal to or not orthogonal to) the first direction. The method further includes depositing a metal fill layer in the plurality of first openings to form probe tips and the plurality of second openings to form probe beams. The method further includes directly bonding a second substrate to the first substrate. A plurality of probe stands (e.g., probe bases) are disposed in the second substrate. The plurality of probe stands extend along the first direction. Directly bonding the second substrate to the first substrate directly bonds each probe stand to a respective probe beam. The plurality of bonded probe stands to the plurality of probe beams create a plurality of probes. The method further includes directly bonding the plurality of probes to a probe card substrate (e.g., an interposer, a translator, or a board) and removing at least portion of the first substrate and at least part of the second substrate. In some embodiments, at least a portion of the first substrate may comprise the first substrate.

In some embodiments, the first substrate comprises a silicon material (e.g., Si). The second substrate may comprise a silicon material (e.g., Si), an oxide material (e.g., SiO₂, Al₂O₃, ZrO₂, TiO₂), or an organic compound material (e.g., polyimide) or engineering polymer. In some embodiments, the first substrate, second substrate, or any suitable substrate such as substrates mentioned in embodiments of the present disclosure may comprise of a particulate or/and filamentary composite material.

In some embodiments, prior to depositing the metal fill layer, the method includes depositing a metal plating layer. A thickness of the metal plating layer may be less than a thickness of the metal fill layer. The metal plating layer may comprise a copper or a gold material. In some embodiments, the metal fill layer comprises a copper or a nickel material.

In some embodiments, removing the first substrate and at least part of the second substrate comprises etching. The method may include etching the first substrate and at least part of the second substrate. In some embodiments, removing the first substrate comprises wet etching or dry etching or dry or wet laser ablation methods. The method may include completely etching the first substrate and partially etching the second substrate to form a structure disposed around the probe stands. The structure may provide structural support to the plurality of probes.

In some embodiments, the second substrate comprises an oxide material and the plurality of probe stands is a plurality of first probe stands. Prior to directly bonding the plurality of probes to the probe card substrate, the method may further comprise directly bonding a third substrate to the second substrate. The third substrate may comprise a plurality of second probe stands to connect to the plurality of first probe stands. In some embodiments, the third substrate comprises an organic compound material (e.g., polyimide) or reinforced super engineering polymer. In some embodiments, an engineering polymer may be a reinforced super engineering polymer. The probe card substrate may comprise an oxide layer.

In some embodiments, a width of the probe tips is smaller than a width of the probe stands. In some embodiments, a thickness of the probe tips and a thickness of the probe stands are a same thickness.

A fourth general aspect for a method of fabricating a probe card includes etching a plurality of first openings in a first substrate, where the plurality of first openings extends in a first direction. The method further includes depositing a metal fill layer in the plurality of first openings to form probe tips. The method may further comprise applying a 3D high temperature metal to fill the opening to form the probe tip. In other embodiments, the structure comprising the probe tip and the probe beam can be 3D printed using a suitable high temperature metal or metals. The printed structure may be for example, in situ laser annealed to densify and strengthen the printed structure.

In some embodiments, the method further includes directly bonding a second substrate to the first substrate. A plurality of probe beams and a plurality of probe stands are disposed in the second substrate. The probe beams extend in a second direction different than (e.g., orthogonal to or not orthogonal to) the first direction, and the probe stands extend along the first direction. In some embodiments, probe beams extend in a second direction non-orthogonal to the first direction, and the probe stands extend along the first direction. Directly bonding the second substrate to the first substrate directly bonds each probe stand to a respective probe beam and generates a plurality of probes. The method further includes directly bonding the plurality of probes to a probe card substrate and removing the first substrate and at least part of the second substrate.

In some embodiments, the method further includes forming a plurality of probe beams in a dielectric layer disposed on the silicon substrate. Each probe beam is in contact with a respective probe tip of the plurality of probe tips, where the plurality of probe beams extend in a second direction different than (e.g., orthogonal to or non-orthogonal to) the first direction. The method further includes directly bonding a second substrate to the first substrate. A plurality of probe stands to connect to a respective probe beam are disposed in the second substrate, where the probe stands extend along the first direction. The plurality of bonded probe stands to the plurality of probe beams and probe tips create a plurality of probes. The method further includes directly bonding the plurality of probes to a probe card substrate and removing the first substrate and at least part of the second substrate.

A fifth general aspect for a method of fabricating a probe card includes etching a plurality of first openings in a probe substrate, where the plurality of first openings extends in a first direction. The method further includes depositing a metal fill layer in the plurality of first openings to form probe tips. The method further includes forming a plurality of probe beams in a first dielectric layer disposed on the probe substrate. Each probe beam is in contact with a respective probe tip of the plurality of probe tips, where the plurality of probe beams extend in a second direction different than (e.g., orthogonal to or non-orthogonal to) the first direction. The method further includes forming a plurality of probe stands in a second dielectric layer disposed on the first dielectric layer, where each probe stand contacts a respective probe beam, to form a plurality of probes. Each probe comprises a probe tip, a probe beam, and a probe stand. The plurality of probe stands extend along the first direction. The method further includes removing at least part of the first dielectric layer and the second dielectric layer, directly bonding the plurality of probes to a probe card substrate, and removing the probe substrate. In some embodiments, the probe tip, the probe beam, and the probe stand may be formed by 3D printing methods. In the 3D printed structures comprising a conductive probe tip, the probe beam and the probe stand may comprise a conductive layer or an embedded conductive layer, connecting the probe tip to the conductive features in the substrate.

### BRIEF DESCRIPTION OF THE DRAWINGS

The above and other objects and advantages of the disclosure will be apparent upon consideration of the following detailed description, taken in conjunction with the accompanying drawings, in which:

FIGS. 1A-1B schematically illustrate views of an example testing setup, in accordance with example embodiments of the present disclosure;

FIG. 1C schematically illustrate views of example probes, in accordance with example embodiments of the present disclosure;

FIGS. 2A-2C schematically illustrate example methods of forming probe cards, in accordance with some embodiments of the present disclosure;

FIGS. 3A-3B schematically illustrate views of an example probe card, in accordance with some embodiments of the present disclosure;

FIGS. 4A-4B schematically illustrate views of an example probe card, in accordance with some embodiments of the present disclosure;

FIGS. 5A-5B schematically illustrate example methods of manufacturing a probe, in accordance with some embodiments of the present disclosure;

FIG. 6 schematically illustrates an example method of manufacturing a probe card, in accordance with some embodiments of the present disclosure;

FIG. 7 schematically illustrates an example method of manufacturing a plurality of probes, in accordance with some embodiments of the present disclosure;

FIG. 8A schematically illustrates an example method of plating a probe tip and a probe beam, in accordance with some embodiments of the present disclosure;

FIG. 8B schematically illustrates an example method of plating a probe beam, in accordance with some embodiments of the present disclosure;

FIG. 9 schematically illustrates an example method of forming a probe card, in accordance with some embodiments of the present disclosure; and FIGS. 10A-10B schematically illustrates a hybrid bonding method, according to some embodiments.

The figures herein depict various embodiments of the disclosure for purposes of illustration only. It will be appreciated that additional or alternative structures, assemblies, systems, and methods may be implemented within the principles set out by the present disclosure.

### DETAILED DESCRIPTION

Embodiments herein may provide for probes, probe structures, and/or probe cards and methods of forming the same. Advantageously, methods and probe structures described herein may provide for probe cards with fine pitch (e.g., less than about 10 μm, less than about 20 μm, less than about 30 μm, less than about 40 μm, etc.) and may enable durable and reliable performance.

As used herein, the term “substrate” means and includes any workpiece, wafer, or article that provides a base material or supporting surface from which or upon which components, elements, devices, assemblies, modules, systems, or features of the probe cards or probes described herein may be formed. The term substrate also includes “semiconductor substrates” that provide a supporting material upon which elements of a semiconductor device are fabricated or attached, and any material layers, features, and/or electronic devices formed thereon, therein, or therethrough. For ease of description elements, features, and devices formed therefrom are referred to in the singular or plural but should be understood to describe both singular and plural, e.g., one or more, unless otherwise noted.

As described below, semiconductor substrates herein generally have a “device side,” e.g., the side on which semiconductor device elements are fabricated, such as transistors, resistors, and capacitors, and a “backside” that is opposite the device side. The term “active side” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that form the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active” and “non-active sides” may be used to describe surfaces of material layers or features formed on, in, or through the semiconductor substrate, whether or not the material layers or features are ultimately present in the fabricated or assembled device.

Spatially relative terms are used herein to describe the relationships between elements, such as the relationships between layers and other features described below. Unless the relationship is otherwise defined, terms such as “above,” “over,” “upper,” “upwardly,” “outwardly,” “on,” “below,” “under,” “beneath,” “lower,” and the like are generally made with reference to the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” either alone or in combination with a spatially relevant term include both relationships with intervening elements and direct relationships where there are no intervening elements.

Various embodiments disclosed herein include bonded structures in which two or more elements are directly bonded to one another without an intervening adhesive (referred to herein as “direct bonding,” “direct dielectric bonding,” or “directly bonded”). The resultant bonds formed by this technique may be described as “direct bonds” and/or “direct dielectric bonds”. In some embodiments, direct bonding includes the bonding of a single material on the first of the two or more elements and a single material on a second one of the two or more elements, where the single material on the different elements may or may not be the same. For example, bonding a layer of one inorganic dielectric (e.g., silicon oxide) to another layer of the same or different inorganic dielectric. Examples of dielectric materials used in direct bonding include oxides, nitrides, oxynitrides, carbonitrides, and oxycarbonitrides, etc., such as, for example, silicon oxide, silicon nitride, silicon oxynitride, silicon carbonitride, silicon oxycarbonitride, etc. Direct bonding can also include bonding of multiple materials on one element to multiple materials on the other element (e.g., hybrid bonding). As used herein, the term “hybrid bonding” refers to a species of direct bonding having both i) at least one (first) nonconductive feature directly bonded to another (second) nonconductive feature, and ii) at least one (first) conductive feature directly bonded to another (second) conductive feature, without any intervening adhesive. The resultant bonds formed by this technique may be described as “hybrid bonds” and/or “direct hybrid bonds”. In some hybrid bonding embodiments, there are many first conductive features, each directly bonded to a second conductive feature, without any intervening adhesive. In some embodiments, nonconductive features on the first element are directly bonded to nonconductive features of the second element at room temperature without any intervening adhesive, which is followed by bonding of conductive features of the first element directly bonded to conductive features of the second element via annealing at slightly higher temperatures (e.g., >100° C., >200° C., >250° C., >300° C., etc.).

Direct bonding may include direct dielectric bonding techniques as described herein, and may give rise to direct dielectric bonds. Hybrid bonding may include hybrid bonding techniques as described herein, and may give rise to direct hybrid bonds.

The hybrid bonding methods described herein generally include forming conductive features in the dielectric surfaces of the to-be-bonded substrates, activating the surfaces to open chemical bonds in the dielectric material, and terminating the surfaces with a desired species. In some embodiments, activating the surface may weaken chemical bonds in the dielectric material. Activating and terminating the surfaces with a desired species may include exposing the surfaces to radical species formed in a plasma. In some embodiments, the plasma is formed using a nitrogen-containing gas, e.g., N₂, or forming gas and the terminating species includes nitrogen and hydrogen. In some embodiments, the surfaces may be activated using a wet cleaning process, e.g., by exposing the surfaces to aqueous solutions. In some embodiments, the aqueous solution is tetramethylammonium hydroxide diluted to a certain degree or percentage. In some embodiments, an aqueous solution may be ammonia. In some embodiments, the plasma is formed using a fluorine-containing gas, e.g., fluorine gas or helium containing a small amount of fluorine and/or nitrogen such as about 10% or less by volume, 9% or less, 8% or less, 7% or less, 6% or less, 5% or less, 4% or less, 3% or less, 2% or less, for example 1% or less.

Typically, the hybrid bonding methods further include aligning the substrates, and contacting the activated surfaces to form direct dielectric bonds. After the dielectric bonds are formed, the substrates may be heated to a temperature between 50° C. to 150° C. or more, or of 150° C. or more and maintained at the elevated temperature for a duration of about 1 hour or more, such as between 8 and 24 hours, to form direct metallurgical bonds between the metal features.

As used herein, the terms “pin” and “probe” may be used interchangeably. As used herein, the terms “probe tip,” “tip,” and “pin” may be used interchangeably. As used herein, the terms “probe beam,”“trace,”“line,”and “patterned metal layer”may be used interchangeably. As used herein, the terms “via,” “trace,” “line,” “probe stand,” “post,” and “probe base” may be used interchangeably. As used herein, the terms “semiconductor device,” “microchip,” “chip,” and “die” may be used interchangeably. As used herein, the terms “probe card” may be the interface between a device and a test system and may enable mechanical and electrical contact between a test system and the device undergoing testing. In some embodiments, the probe card may be one or more probes or contact elements on a substrate (e.g., printed circuit board (PCB) or interposer).

As more and more chips are being combined together, it may be desirable to have the ability fully test each chip or die for functionality (e.g., probe every pad of the chip or die). As dies on chip packages become smaller the probes and the pitch between probes may become smaller. Creating smaller probes with reduced pitch size may increase manufacturing cost of a prober or probe card while also decreasing the lifetime of the probe card (e.g., number of cycles the probe card may be used in testing). As pitch gets smaller, testing becomes more difficult. Area array testing may become more difficult to perform due to large pin numbers, fine pitch and area array, assembly warpage, displacement requirement, and high speed. A fine pitch or very fine pitch may result in a large pin density. Large pin numbers may require high force or very high forces to be applied (e.g., for all pins to make contact to bond pads of a device) which may make it difficult to test.

In some approaches, a testing stack up or setup may include a device (e.g., chip) and/or package with pads to be tested and a testing system. The testing system may include a duct board, a translator, and a prober. The duct board may drive the flatness and may have up to or about 60 layers. The translator may be on the duct board, and may be up to about 12 layers and may have L/S (line/spacing) of about 5-10 microns. The translator may be a substrate (e.g., board, small board, PCB, etc.) used to test and for alignment. A prober may be a substrate with one or more pins or probes attached to the substrate. In some embodiments, the prober may be electrically coupled and, in some cases, bonded to the translator. When the probes contact the bond pads of the device, electrical input/output signals may be generated by the testing system to test die functionality. The prober may have pins at a fine pitch and may include about 80,000 pins.

In some approaches, probes may be plunger prober pins, wire pins, interposer with pins, or plated pins (e.g., formed on board). Plunger prober pins may have pins on both ends with a spring inside (e.g., to make a temporary contact on both sides of probe with pins on each side), or may have pins on one side of the probe (e.g., other side of pin attached via solder connection to a translator). Plunger probe pins may have difficulty to make fine pitch due to its structure. Wire pins may be formed between two substrates or plates. Holes may be formed in the plates, a wire may be inserted into each hole, and the wire may be bent. One end of the wire may be soldered, and the other side may be the pin. For example, one substrate may be moved relative to the other to create a bend in the pin or wire. With wire pins, the wire may have to be long (e.g., very long) and the co-planarity of the pins may be a problem and may require large force to be applied (e.g., for all pins to contact a device under test). An interposer with pins may be a silicon interposer with wire bond as probe, or a cantilever formed or plated on a silicon interposer. The interposer with pins may be attached to a board (e.g., translator, substrate). For plated pins, the cantilever may be formed or plated on a board (e.g., translator, substrate).

In some embodiments, one or more probes, probe array, probe card, or probe apparatus are made using direct bonding or hybrid bonding (e.g., Direct Bond Interconnect or DBI®, technology). For example, a probe or probe card may be made using direct bonding or hybrid bonding with an organic or a non-organic material. In some embodiments, a probe or probe card may be made using direct bonding or hybrid bonding with a dielectric layer (e.g., oxide) on an organic material. In some embodiments, a probe array with a fine pitch (e.g., under about 50 microns, under about 40 microns, under about 30 microns, under about 20 microns, under about 10 microns) may be formed on a substrate comprising organic and/or non-organic material.

In some embodiments, one or more pins (e.g., probes) may be formed in a first substrate (e.g., silicon), and then transferred via DBI to a second substrate (e.g., an interposer, translator, board, PCB, etc.). For example, one or more probes comprising a probe tip (e.g., pin), a probe beam (e.g., wire), and a probe stand (e.g., via) may be formed in a first substrate. In some embodiments, the first substrate comprises an inorganic material (e.g., silicon substrate or wafer), and may further comprise dielectric and/or organic materials. The first substrate may comprise a plurality of bonded substrates and/or a plurality of layers. Probe(s) may be formed in the first substrate, and the first substrate with the probes formed therein may be referred to as a probe wafer. The probe wafer may be directly bonded or hybrid bonded to a second substrate (e.g., board, PCB, translator, interposer, etc.). A surface of the second substrate may comprise a dielectric layer (e.g., oxide) on organic material and one or more conductive features disposed in the dielectric layer. After bonding, the first substrate (e.g., silicon) or portions of the first substrate may be etched or removed. In some embodiments, the first substrate is completely removed, and only the one or more probes may remain directly bonded (e.g. by direct metal to metal bonds) to the one or more conductive features on the second substrate. In some embodiments, portions of the first substrate is removed, and one or more probes disposed in a structural support structure (e.g., remaining portions of the first substrate, silicon or dielectric material remaining after removal of a portion the first substrate) may remain directly bonded (e.g., by direct hybrid bonds such as metal to metal bonds and dielectric to dielectric bonds) on the second substrate. Because features of the probe may be made in silicon, a fine pitch (e.g., very fine pitch) of a plurality of probes or a probe array may be formed, and a sharp pin (e.g., probe tip) may be formed in silicon via a suitable etch.

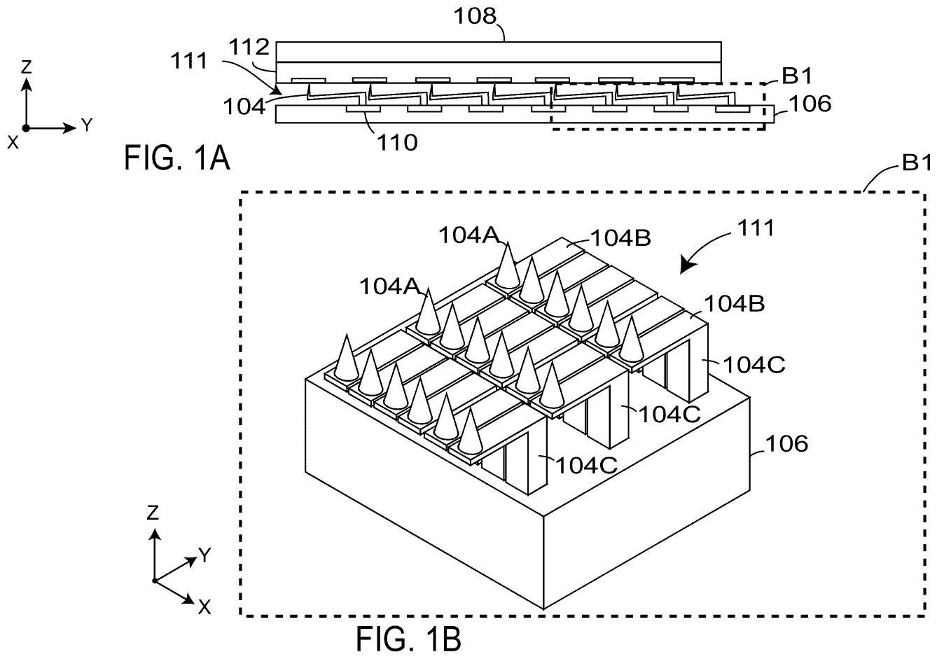

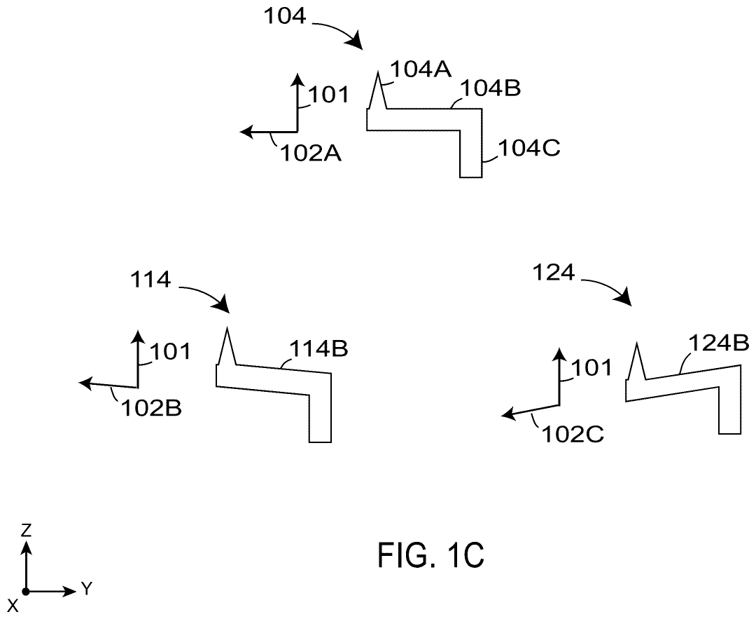

FIG. 1A schematically illustrate views of an example testing setup, in accordance with example embodiments of the present disclosure. The testing setup may include a chip and/or package or semiconductor device 112 and a testing system. In some embodiments, the semiconductor device 112 may be attached, fixed to, or held by a carrier substrate, carrier plate, plate, chuck, or assembly 108. The testing system may comprise a prober or probe card 111. A portion of a prober or probe card 111 of FIG. 1A is shown in more detail in FIG. 1B. The prober or probe card 111 of FIG. 1A may be used with any suitable components of a testing setup, such as those described above in the present disclosure. The probe card 111 may comprise one or more probes (shown as a plurality of probes 104 in FIG. 1A) attached to a substrate 106. The substrate 106 may be an interposer, board, PCB, translator, etc. Each probe 104 may be a cantilever probe. Each probe 104 may comprise a probe base (e.g., probe stand 104C), a probe beam 104B, and a probe tip 104A. Each probe 104 may be directly bonded or hybrid bonded (e.g., DBI bonded) to a substrate 106. For example, the probe stand 104C of a probe 104 may be directly bonded or hybrid bonded to a substrate 106.

In some embodiments, the semiconductor device 112 may comprise one or more dies with one or more pads. During testing, the one or more pads of each die may be in contact with one or more probe tips 104A of the probe card 111. The spacing of the probe tips 104A may correspond to a spacing of the pads and/or a spacing of the one or more dies of the semiconductor device 112. For example, the distance between a first die and a second die on a chip/package or semiconductor device 112 (e.g., center of each die, corresponding pad of each die) may be about 20 μm, and a probe card 111 may include probes where probe tips 104A on the probe array are distanced at about 20 μm. In some embodiments, the probe card 111 comprises probe pairs configured to test input/output (I/O) electrical signals of the semiconductor device 112. For example, a probe pair may comprise a first probe and a second probe, the first probe may be configured to transmit electrical signals from the substrate 106 (e.g., interposer) to a die of the semiconductor device 112 and the second probe may be configured to receive electrical signals from the die of the semiconductor device 112. Continuing with the earlier example, where the distance between a first die and a second die on a semiconductor device 112 may be around 20 μm, the probe pairs may have spacing less than about 20 μm, and each probe pair may be spaced apart from another probe pair by about 20 μm. In some embodiments, there may be a group of probes (e.g., two or more probes) per each die (e.g., each die may have two or more corresponding pads) and the distance between the probes within a group of probes be less than about a pitch of the dies, and the distance between groups of probes may be about the pitch of the dies.

FIG. 1B shows a schematic isometric view of a portion of a prober or probe card 111, in accordance with some embodiments of the present disclosure. FIG. 1B may illustrate a zoomed and shifted observational view of the box labeled B1 in FIG. 1A. Each probe stand 104C may be directly bonded to a bond pad 110 (not shown for purposes of simplicity, in FIG. 1B). Although seven probes are shown in y-direction (e.g., cross section of FIG. 1A), and six probes are shown in an x-direction (e.g., perspective view of FIG. 1B), any suitable number of probes (e.g., 1, 2, 3 or more, 10s, 100s, thousands, millions, etc.) may be in the y-direction and in the x-direction of a probe card 111. FIG. 1A shows bond pads 110 being larger than a size of a probe stand 104C (e.g., a length or width of a probe stand). In some embodiments, the bond pad 110 may be any suitable size. For example, a bond pad 110 may be about a same, similar, or a smaller size than the probe stand 104C.

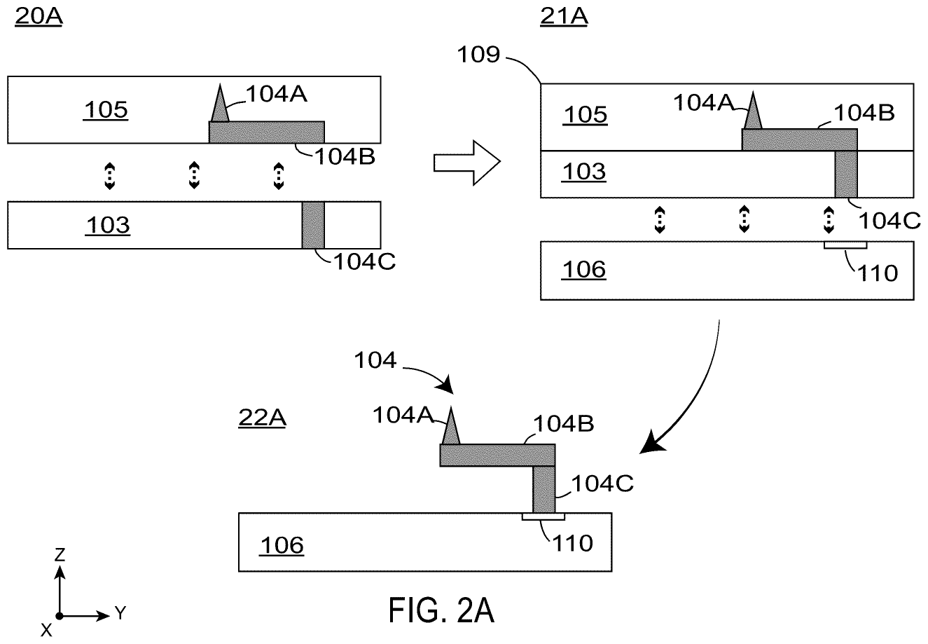

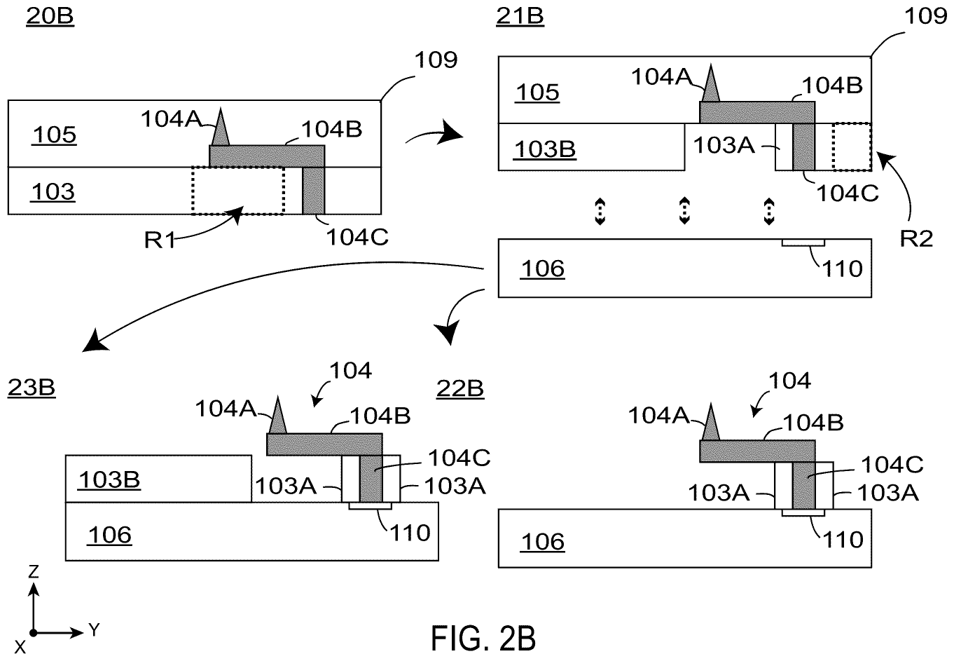

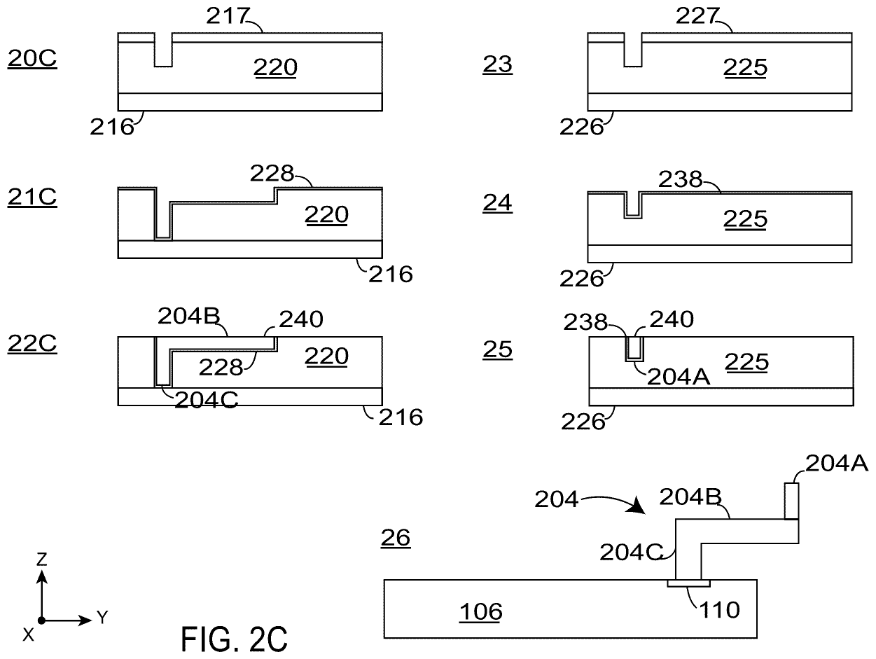

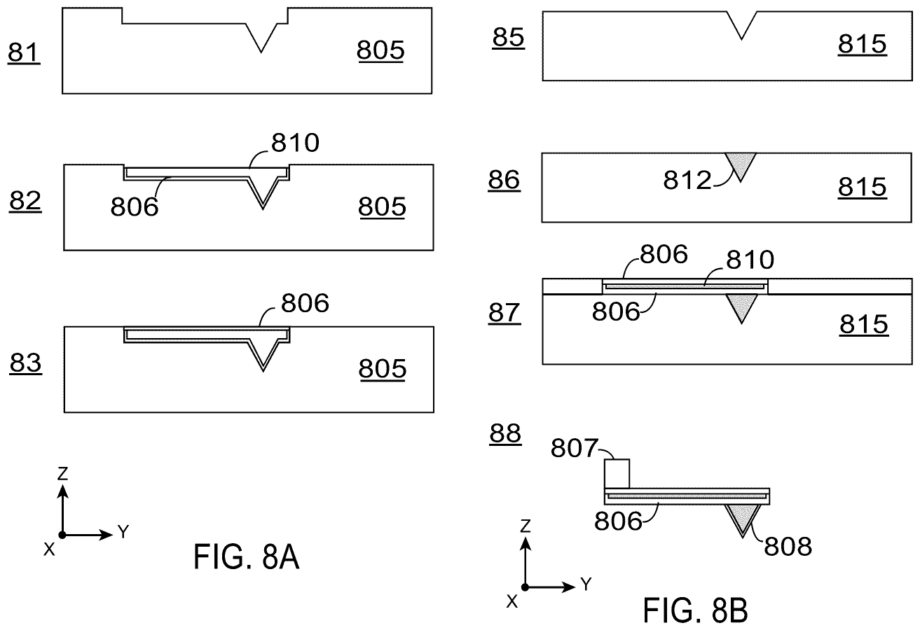

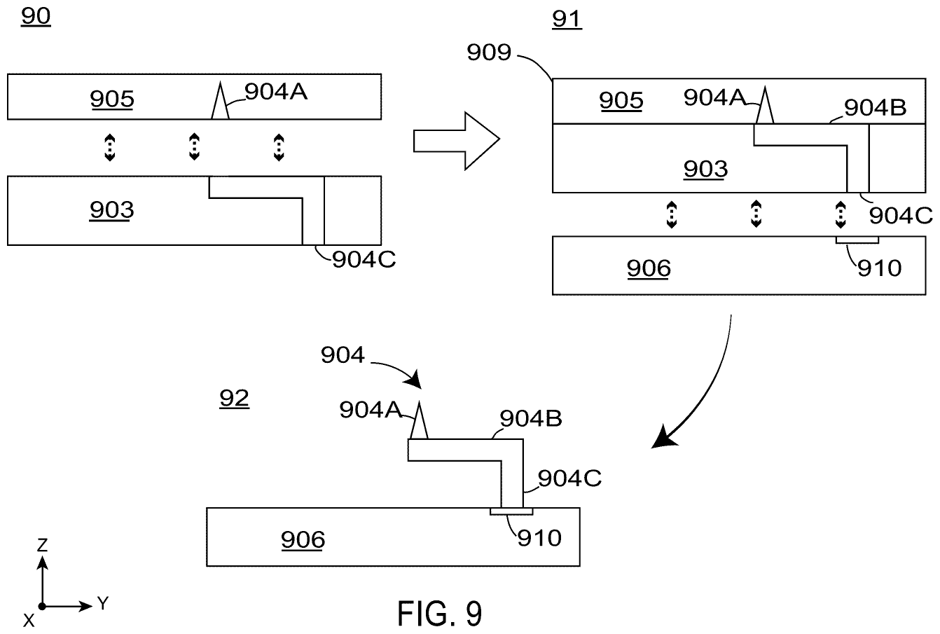

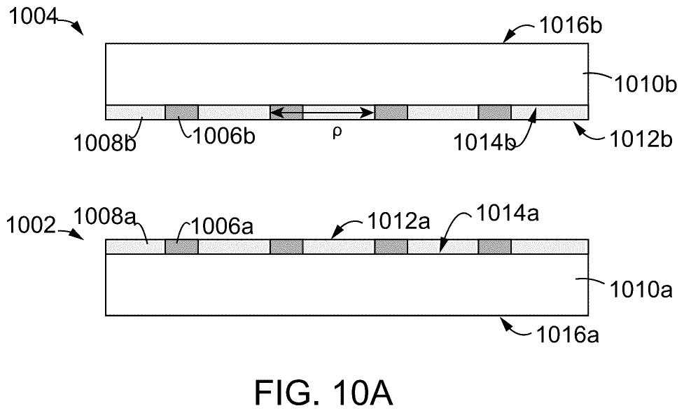

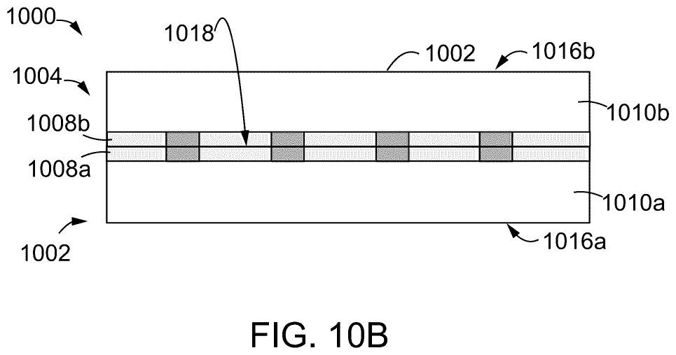

FIG. 1C schematically illustrate views of example probes, in accordance with example embodiments of the present disclosure. FIG. 1C shows examples of probes (e.g., probe 104, probe 114, and probe 124). Probe 104 comprises a probe tip 104A and probe stand 104C extending in a first direction 101 (e.g., Z direction), and a probe beam 104B extending in a second direction 102A orthogonal to the first direction 101. Probe 114 is the same as or similar to probe 104, except that probe 114 includes a probe beam 114B in place of probe beam 104B. The probe beam 114B may be the same as or similar to probe beam 104B except probe beam 114B extends in a second direction 102B that is not orthogonal to the first direction 101. Probe 124 is the same as or similar to probe 104, except that probe 124 includes a probe beam 124B in place of probe beam 104B. The probe beam 124B may be the same as or similar to probe beam 104B except probe beam 124B extends in a second direction 102B that is not orthogonal to the first direction 101. For example, probe 104 may have probe beams 104B that extends in a direction orthogonal to the probe tip 104A and the probe stand 104C when there is no applied pressure to the probe. As another example, probes 114 and 124 may have probe beams 114B and 124B that extend in second directions that are not orthogonal to the first direction when there is no applied pressure the probe. In some embodiments, the probe beams 104B, 114B, and 124B, may be applied to any suitable probe beam of probes in embodiments described in the present disclosure (e.g., any of probe beams 204B, 304B, 404B, 414B, 504B, 604B, 704B, 714B of FIGS. 2A-7, probe beam in FIGS. 8A-8B, probe beams 904B of FIG. 9, etc.). For example, as shown, probe beams in FIGS. 2A-9 may extend in a second direction that is orthogonal to the first direction, similar to probe beam 104B. In other examples, the probe beams in FIGS. 2A-9 and may extend in a second direction that is not orthogonal to the first direction (e.g., probe beam 114B or probe beam 124B used in place of probe beams of FIGS. 2A-9). FIGS. 2A-2C show example methods of forming a probe 104, in accordance with some embodiments of the present disclosure. In some embodiments, a probe 104 (e.g., probe structure, probe) comprises a probe tip 104A, a probe beam 104B, and a probe base (e.g., probe stand 104C). In some embodiments, a probe comprises a probe beam and a probe stand. In some embodiments, a probe tip 104A may be referred to as a “pin”, a probe beam 104B may be referred to as a “line” or “trace” and a probe base (e.g., probe stand 104C) may be referred to as a “via.” Although FIGS. 2A-2C shows an example method of forming a single probe 104, any suitable number of probes may be formed by the methods.

FIG. 2A shows a block schematic to illustrate a method of forming a probe, in accordance with some embodiments of the present disclosure. A first substrate 105 and a second substrate 103 are bonded (e.g., directly bonded, directly hybrid bonded) at block 20A prior to directly bonding the probe (e.g., probe stand) to a conductive feature or bond pad 110 on a third substrate 106 at block 21A. Portions of the first substrate 105 and second substrate 103 may be removed to form the probe card comprising the probe 104 attached to the substrate 106 at block 22A.

At block 20A, the method may include providing a first substrate 105 and a second substrate 103. In some embodiments, a probe tip 104A and a probe beam 104B is disposed in the first substrate 105. For example, the first substrate 105 may comprise a first material, and a probe tip 104A and probe beam 104B may be formed or disposed in a first material (e.g., silicon material). The second substrate 103 may comprise a second material, and a probe base (e.g., probe stand 104C) may be formed or disposed in the second material (e.g., silicon, oxide, organic, any suitable material, etc.).

Subsequent to block 20A and prior to block 21A, the first substrate 105 and the second substrate 103 are bonded to form a workpiece (e.g., workpiece 109 as shown at block 21A). The method may include bonding (e.g., directly bonding, directly hybrid bonding) the first substrate 105 and second substrate 103. In some embodiments, the first substrate 105 and second substrate 103 comprise a same material (e.g., silicon). In some embodiments, the first substrate 105 and second substrate 103 comprise different materials. For example, the first substrate 105 may comprise silicon while the second substrate 103 may comprise organic material (e.g., polyimide or engineering polymer). The probe beam 104B and the probe stand 104C may comprise a same material or different materials. Additional detail regarding direct bonds, direct bonding, hybrid bonds, and hybrid bonding of substrates may be found in the present disclosure, e.g., at least at the description of FIGS. 10A-10B.

At block 21A, the method may include providing a third substrate 106. The third substrate 106 comprises at least one bond pad 110 (e.g., conductive feature). In some embodiments, the third substrate 106 is a board, PCB, an interposer, translator, etc.

Subsequent to block 21A and prior to block 22A, the workpiece 109 (e.g., bonded first and second substrates 105, 103) is bonded to a third substrate 106. The method may include bonding (e.g., directly bonding, directly hybrid bonding) the workpiece 109 or the second substrate 103 to the third substrate 106. For example, the probe stand 104C may be directly bonded to the bond pad 110 (e.g., via direct metal bonds), and the second material (e.g., organic, oxide, etc.) of the second substrate 103 and a third material (e.g., organic, oxide, etc.) of the third substrate 106 may be directly bonded to each other (e.g., via direct dielectric bonds). DBI bonding can occur between organic or inorganic material. Additional detail regarding direct bonds, direct bonding, hybrid bonds, and hybrid bonding of substrates may be found in the present disclosure, e.g., at least at the description of FIGS. 10A-10B.

At block 22A, the method may include removing portions of the first substrate 105 and the second substrate 103. For example, portions of the first material (e.g., silicon) of the first substrate 105 and the second material (e.g., silicon, oxide, etc.) of the second substrate 103 may be removed. In some embodiments, the first substrate 105 is completely removed, and portions of the second substrate 103 is removed. For example, portions of the second material of the second substrate 103 surrounding the probe base (e.g., probe stand 104C) may remain to provide structural support for the probe stand 104C. In some embodiments, the first substrate 105 and the second substrate 103 may each comprise a silicon material, the first substrate 105 may be completely removed and portions the second substrate 103 and may be removed by wet etching the silicon. In some embodiments, the second substrate 103 may be removed by dry etch or dry or wet laser ablation methods.

In some embodiments, the probe 104 (e.g., probe tip 104A, probe beam 104B, and probe stand 104C) may be formed in a silicon or an inorganic material. In some embodiments, the probe tip 104A is formed in silicon, and the probe beam 104B and probe stand 104C are formed in a dielectric material or an organic material (e.g., polyimide or PI, or engineering polymer, etc.). For example, a probe tip (e.g., probe tip 904A of FIG. 9) may be formed in silicon (e.g., a first substrate 905 of FIG. 9) and a probe beam and probe stand (e.g., probe beam 904B and probe stand 904C of FIG. 9) may be formed in an organic layer (e.g., second substrate 903 of FIG. 9). In some embodiments, an oxide layer on an organic layer may be used in place of an inorganic material, dielectric material, or an organic material.

In some embodiments, a probe or probe card may be formed using one or more features related to a wide area vertical expansion (WAVE™) technique. In some approaches, a WAVE technique directly plates probes onto a substrate. For example, a first polyimide layer may be deposited on a substrate, and a via may be made formed in the first polyimide layer and then plated. A second polyimide layer may be deposited, a trace may be formed in the second polyimide layer and plated. A solder ball may be attached to the plated trace, and then the polyimide may be etched.

In some embodiments, a probe tip may be formed in silicon or a silicon substrate. A first layer of polyimide may be deposited on the silicon, a trace may be formed in the first polyimide layer and plated (e.g., a probe beam may be formed in the first layer of polyimide). A second layer of polyimide may be deposited on the first layer of polyimide, a via may be formed in the second layer and plated (e.g., and a probe stand may be formed in the second layer of polyimide). In some embodiments, a first substrate or probe wafer comprises a silicon substrate with the probe tip in the silicon substrate and the organic layer (e.g., first and second polyimide layer) with the probe beam and probe stand in the organic layer. The first substrate or probe wafer may be bonded to the second substrate (e.g., similar or same as substrate 906 of FIG. 9), and the method may include removal of silicon and then plasma removal of organic layer (e.g., similar to block 92 of FIG. 9). In some embodiments, the probe beam and probe stand may be formed in polyimide (e.g., polyimide tape), and the probe beam and/or probe stand may be released from polyimide before bonding.

FIG. 2B schematically illustrates an example method of forming a probe card, in accordance with some embodiments of the present disclosure. The probe card comprises one or more probes (shown as one probe 104 comprising a probe tip 104A, probe beam 104B, and probe stand 104C with the probe stand 104C disposed in a support structure 103A) attached to a substrate 106. Support structure 103A surrounds a probe base (e.g., probe stand 104C) and provides structural support to the probe 104 (e.g., reinforcing the probe stand 104C, providing mechanical support to the cantilever structure). The support structure 103A may comprise an inorganic material (e.g., silicon) or a dielectric material (e.g., oxide) or organic material such an underfill layer or a low CTE (coefficient of thermal expansion) organic encapsulant.

At block 20B, the method includes providing a workpiece 109. In some embodiments, the workpiece 109 is formed by attaching (e.g., bonding, directly bonding, directly hybrid bonding) the first substrate 105 with the second substrate 103. Subsequent to providing the workpiece 109 at block 20B, the method may include removing a first portion R1 of the second substrate 103 to create a cavity below the probe beam 104B before attaching the workpiece 109 to the third substrate 106.

At block 21B, the method may include providing the third substrate 106. The method may further include removing a second portion R2 of the second substrate 103 as indicated at block 21B to form the support structure 103A around the probe stand 104C. In some embodiments, the method includes removing the first portion R1 and the second portion R2 of the second substrate 103 indicated at blocks 20B and 21B at a same or similar time (e.g., prior to bonding workpiece 109 to the third substrate 106). In some embodiments, the method includes removing the second portion R2 of the second substrate 103 subsequent to bonding the workpiece 109 to the third substrate 106. In some embodiments, the second substrate 103 may be removed by wet etching. In some embodiments, the second substrate 103 may be removed by dry etch or dry or wet laser ablation methods Subsequent to block 21B and prior to block 22B, the workpiece 109 is bonded (e.g., directly bonded, hybrid bonded) to the third substrate 106. For example, at block 22B or at block 23B, the workpiece 109 or second substrate 103 is DBI bonded to the third substrate 106 (e.g., board, PCB, interposer, translator, etc.). In some embodiments, the bond pads 110 on third substrate 106 may be a similar size or smaller than a size of the probe stand 104C. For example the probe stand 104C and bond pad 110 may be directly bonded (e.g., via direct metal bonds), and a surface of the support structure 103A and portions of a surface of the third substrate 106 may be directly bonded (e.g., via direct dielectric bonds).

In some embodiments, a material layer (e.g., organic, dielectric, oxide) is formed on the first substrate 105 (e.g., silicon substrate or wafer) in place of the second substrate 103. For example, the method may include forming a material layer on the first substrate 105. The method may include forming a probe stand 104C disposed in the material layer. For example, an opening may be formed in the material layer to expose at least a portion of the probe beam 104B. The opening may be filled with a metal fill layer to form probe stand 104C in direct contact and connected to probe beam 104B. In some embodiments, the method may include removing portions of the material layer to form a cavity that a portion of the probe 104 (e.g., probe beam 104B) may enter.

In some embodiments, portions of the dielectric layer or portions 103B of substrate 103, as shown at block 23B, formed on the first substrate 105 may remain to define a cavity (e.g., space where probe beam 104B may deflect into). For example, subsequent to block 21B, the first substrate 105 (e.g., comprising a silicon material) is removed, and the patterned portions of a dielectric layer (e.g., support structure 103A and portions of dielectric layer or portions 103B of substrate 103) remain bonded to the third substrate 106. In some embodiments, a dielectric layer (e.g., oxide) may be a top layer of the third substrate 106 (e.g., board, PCB, interposer, translator, any suitable substrate comprising organic material, etc.). The support structure 103A and portions of the dielectric layer or portions 103B of substrate 103 may be directly bonded to the third substrate 106 via direct dielectric bonds.

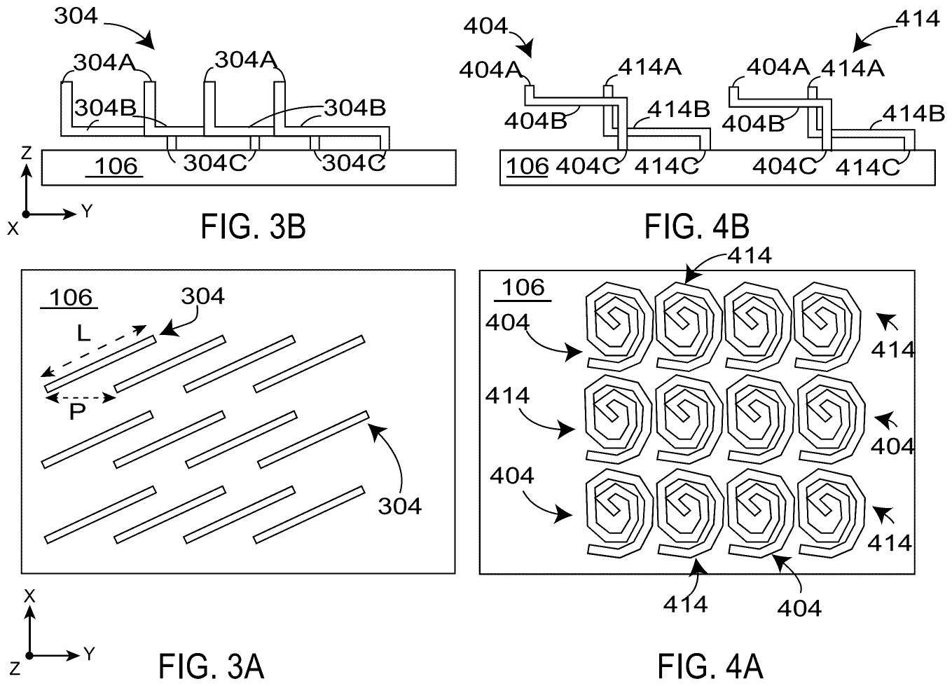

FIG. 2C shows a multi-step/block schematic to form a pin structure or probe 204, in accordance with some embodiments of the present disclosure. In some embodiments, the probe structure is without a sharp tip or a tip with a triangular cross-section in a YZ plane (e.g., probe structure in FIGS. 3B and 4B). In some embodiments, the probe structure includes a sharp tip or a triangular cross-section in a YZ plane (e.g., although not shown, probe structure in FIGS. 3B and 4B may include a sharp tip). Blocks 20C-22C may show an example method of forming a probe stand and probe beam, and blocks 23-25 may show an example method of forming a probe stand. In some embodiments, blocks 20C-22C may be applied to forming a probe tip and probe beam instead of a probe stand 204C and probe beam 204B, and blocks 23-25 may be applied to forming a probe stand.

FIG. 2C shows a damascene process (e.g., dual-damascene fabrication process, singular, or other) may be used to create the probe 204. At block 20C, a first substrate 216 and second substrate 220 are provided. In some embodiments, the first substrate 216 is a carrier. In some embodiments, the first substrate 216 and second substrate 220 comprise a same material (e.g., silicon, organic, PI). In some embodiments, an interlevel dielectric (ILD) may be in place of the second substrate 216. The method may include depositing photoresist on the second substrate 220, exposing and patterning the photoresist 217, and etching the second substrate 220 to form a first opening in a first direction (e.g., Z direction).

Subsequent to block 20C and prior to block 21C, the patterned photoresist 217 may be removed, and a similar approach to block 20C may be used to form a second opening in a second direction orthogonal to the first direction (e.g., Y direction). In some embodiments, the second opening may be formed in a second direction that is non-orthogonal to the first direction (e.g., second direction 102B, 102C different than the first direction 101, as shown in FIG. 1C). Using lithography and etching techniques, openings in a first direction and a second direction may be formed. In some embodiments, the second opening may be formed prior to the first opening (e.g., opening along a Y direction may be formed prior to an opening along the Z direction).

At block 21C, the method may include depositing a diffusion barrier material 228 (e.g., barrier layer) in the first and second opening formed in the second substrate 220. In some embodiments the diffusion barrier material 228 may comprise tungsten (W), titanium-tungsten alloy (TiW) titanium nitride (TiN), tantalum (Ta), tantalum nitride, nickel, nickel alloys (NiP, NiZr, NiW) cobalt, cobalt alloys (coP, NiB), cobalt-nickel alloy or a combination thereof. After the barrier layer coating, a suitable seed layer (not shown) maybe coated over the barrier layer (e.g., diffusion barrier material 228). In some embodiments the barrier layer, for example Ni or NiZr may serve as the seed layer.

At block 22C, the method may include depositing a metal fill material 240 in the first and second opening (e.g., Cu, Au, Ag, etc.). In some embodiments, the metal fill material 240 deposited in the first opening creates either a probe tip 204A or a probe stand 204C, and the metal fill material 240 deposited in the second opening creates a probe beam 204B. In some embodiments, the metal fill material 240 is deposited on the substrate 220, and the unwanted overburden of the metal fill material 240 and unwanted diffusion barrier material 228 may be removed from field surfaces of the substrate 220 (e.g., via CMP). For example, excess metal fill material 240 and excess diffusion barrier material 228 may be removed or planarized (e.g., by chemical mechanical polishing process (CMP)). In some embodiments, the diffusion barrier material 228 prevents diffusion of the metal fill material 240 into the second substrate 220. In some embodiments, the diffusion barrier material 228 is a metal plating material to enhance electrical conductivity of the probe structure (e.g., probe beam 204B and probe stand 204C).

In some embodiments, blocks 23-25 describe the process to create a probe tip 204A. Blocks 23-25 may include similar features or components to blocks 20C-22C described above, and therefore the description of similar features is omitted for brevity.

At block 23, a first substrate 226 and a second substrate 225 are provided. In some embodiments, the first substrate 226, the second substrate 225, and patterned photoresist 227 of block 23 is similar to the first substrate 216, the second substrate 220, and the patterned photoresist 217 of block 20C, respectively. At block 23, similar to block 20C, an opening in a first direction (Z direction) is created in a second substrate.

At block 24 a diffusion barrier material 238 is deposited on the second substrate 225. In some embodiments, the diffusion barrier material 238 is similar to or the same as the diffusion barrier material 228 at block 21C. At block 24, similar to block 21C, a diffusion barrier layer is deposited on a second substrate.

Subsequent to block 24, and prior to block 25, an overburden of the diffusion barrier layer 228 may be removed from a field surface of the second substrate 225. The method may include depositing a metal fill material 240 on the diffusion barrier material 238. In some embodiments, the metal fill material 240 is deposited over the second substrate 225 and an overburden of the metal fill material 240 may be removed from the field surface of the second substrate 225. For example, excess metal fill material 240 and excess diffusion barrier material 238 may be removed or planarized (e.g., by chemical mechanical polishing process (CMP)).

In some embodiments, the probe tip 204A formed at block 25 is attached (e.g., directly bonded, directly hybrid bonded) to the probe beam 204B formed at block 22C to form a probe 204.

At block 26, the probe stand 204C of the probe 204 is attached to a bond pad 110 the third substrate 106. In some embodiments, the probe 204 and the bond pad 110 are directly bonded (e.g., via direct metal bonds).

There are various ways of creating pins (e.g., free standing pins) on silicon or organic. In some embodiments, nested traces on one layer or multiple layers may be used because of the fine pitch. In some embodiments, designs of pins, free standing pins, and/or pin arrays formed using the WAVE™ technique or any other suitable technique may be formed using the techniques described herein in this disclosure.

FIG. 3A shows a top-down schematic view of an example probe array, in accordance with some embodiments of the present disclosure. In some embodiments, a plurality of probes 304 are attached to an interposer (e.g., third substrate 106). In some embodiments, the plurality of probes 304 are plated probes comprising a metal or alloy capable of conducting electricity (e.g., Au).

FIG. 3B shows a side schematic view of FIG. 3A illustrating an example probe array, in accordance with some embodiments of the present disclosure. In this illustrative example, the probe tip 304A of the cantilever probe 304 may be larger than the probe base 304C. In one approach, the length L of the probe beam 304B is greater than the probe pitch P. One example of nesting traces is shown at FIG. 3B. Nesting traces may have better z-travel compared to traces that are not nested.

FIGS. 4A-4B show schematic views of example probe arrays, in accordance with some embodiments of the present disclosure. FIG. 4A is a top-down schematic view of example probe arrays, while FIG. 4B shows a schematic side view of the array configuration illustrated in FIG. 4A. In the example probe array illustrated in FIGS. 4A-4B, the probe array comprises an alternating probe configuration of a first probe 404 and a second probe 414. In some embodiments, the first probe 404 comprises a probe tip 404A, a probe beam 404B and a probe base 404C, the probe beam 404B is at a first height. In some embodiments, the second probe 414 comprises a probe tip 414A, a probe beam 414B and a probe stand 414C, the probe beam 414B is at a second height different to the first. In some embodiments, the probe is a cantilever probe in the shape of a spiral. In some embodiments, both the probe tip of the first probe (e.g., probe tip 404A) and the probe tip of the second probe (e.g., probe tip 414A) reach the same height. For example, the probe tips 404A, 414A of the first probe 404 and the second probe 414 may be substantially co-planar in a first plane. The probe beams 404B of the first probes 404 may be substantially co-planar and in a second plane different than the first plane, and the probe beams 414B of the second probe 414 may be substantially co-planar and in a third plane different than the first plane and the second plane. In one approach, the two levels of trace routing are shown at FIG. 4B. Two levels of trace routing may be used to achieve longer beams and more z-travel.

For fine pitch, it may be preferred to have a line of testing (trace) or probe beam that is longer than the pitch of the pads. A longer cantilever may give better flexibility and enable lower forces to be applied to cantilever when testing (e.g., lower strain on cantilever). A shorter cantilever may not be as flexible, and may need higher force on cantilever when testing (e.g., higher strain on cantilever). Each line for a cantilever may go into the space associated with another pad. The length of the cantilever may be longer than a pitch of the pads. In a configuration with traces that are in a spiral shape, the lines or traces are not touching other ones because they overlap at different levels. The spiral may be circular in shape, or may be any suitable shape (e.g., may have lines and /r angles).

In some embodiments, the probes of FIG. 3A-3B and FIG. 4A-4B may have probe beams 304B, 404B that extend in second directions that are not orthogonal to the first direction, similar to the probes 114 and 124 of FIG. 1C.

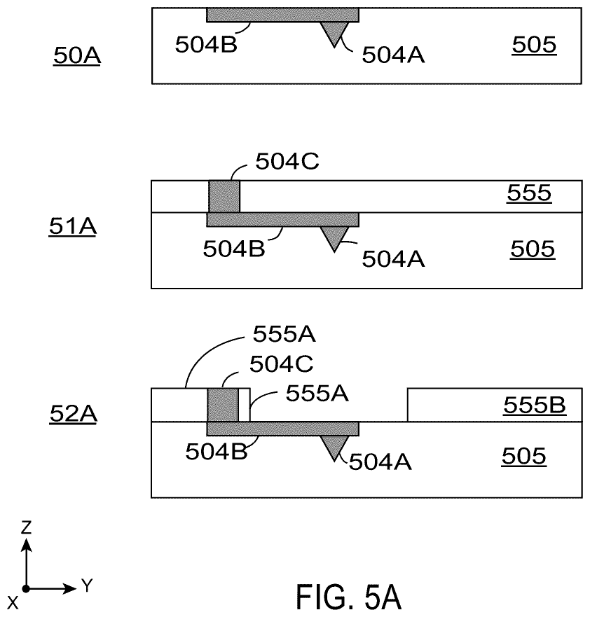

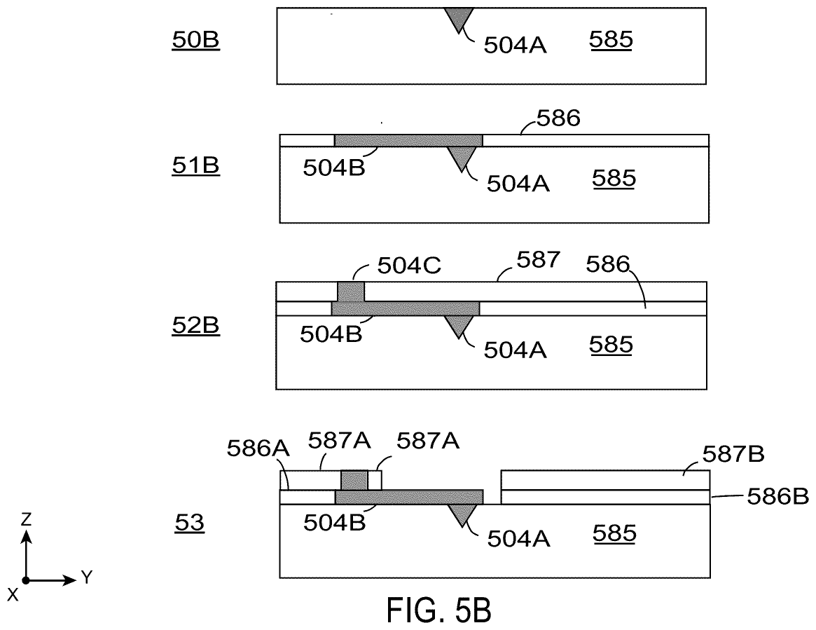

FIGS. 5A-5B show example methods of manufacturing probe(s) (e.g., pin(s)), in accordance with some embodiments of the present disclosure. Although formation of one or two probes are shown, the method may form any suitable number of probes (e.g., 2 or more, hundreds, thousands, millions of probes, etc.). The formed probes (e.g., probe tips) may be co-planar, which may help enable a lower applied force when used in testing (e.g., lower strain in cantilever, lower angle of deflection). The deflection (e.g., change in position or z height of a probe tip to its position without applied force) may be less than a few microns. When probe heights (e.g., z position without applied force) are different across an array, higher forces may be applied to ensure all probes are in contact with the device under test (e.g., semiconductor device to be tested). With different probe heights and a high force being applied, a tallest probe may have the highest strain. Taller probes may have higher strain than lower probes. For example, a taller probe may undergo larger deflection so that a lower probe may also make contact with a surface (e.g., surface of the device to be tested). Advantageously, the features of methods disclosed herein (e.g., methods described in relation to FIGS. 2A-2C, 5A-5B, 6, 7, 8A-8B, 9, and 10A-10B and any other suitable methods as described in embodiments the present disclosure) may minimize or reduce a height difference across an array of probes.

FIG. 5A shows an example method of manufacturing a probe, in accordance with some embodiments of the present disclosure. FIG. 5A shows a probe tip 504A and a probe beam 504B formed in a substrate 505 and a probe stand 504C formed in a dielectric layer 555. In some embodiments, the dielectric layer 555 may be similar to substrate 103, except dielectric layer 555 is formed on substrate 505 instead of the substrate 103 being bonded to substrate 105. A cavity is etched in the dielectric layer 555. The probe tip 504A, probe beam 504B, and probe stand 504C may be formed using any suitable conductive materials, such as those described in the present disclosure.

At block 50A, the method includes etching a probe shape (e.g., probe cavity) into a substrate 505 (e.g., silicon). In some embodiments, the probe shape or opening includes an opening for a probe tip 504A and a probe beam 504B. The method includes filling the probe cavity with a conductive material (e.g., metal, any suitable conductive material). Subsequent to filling the probe cavity with a conductive material a probe tip 504A and a probe beam 504B is formed in the substrate 505.

In some embodiments, the etching and filling the probe cavity may be done using a damascene process. The filling the probe cavity may be done by plating with copper or any suitable conductive material (e.g., copper, nickel, metal alloy, tungsten (W), Ti W alloy, TiN, bilayer of Ti and Ti W) and combinations thereof. The probe tip 504A may comprise any suitable conductive material and may be plated with gold or gold alloy, rhodium or hard precious metal (e.g., a copper tip may be coated with nickel or nickel alloy and the nickel layer plated with gold or gold alloy). The material may be any suitable material that can withstand more than about 100,000 cycles, more than about 50,000 cycles, more than about 20,000 cycles, or more than about 10,000 cycles.

At block 51A, the method includes adding a probe base (e.g., probe stand 504C) to the probe structure. For example, a probe stand 504C (e.g., conductive base or stand) may be disposed in a dielectric layer 555 (e.g., oxide, plurality of) on a portion of the conductive material (e.g., probe beam 504B) disposed in the substrate 505. In some embodiments, adding the probe stand 504C to the probe structure (e.g., probe stand, probe base, and probe tip) may be performed using a damascene process. The probe stand 504C may comprise any suitable conductive material, such as those described in the present disclosure.

At block 52A, the method includes etching a portion of the dielectric layer 555 (e.g., oxide) from a probe area to form the patterned dielectric layer (e.g., support structure 555A and portion 555B of dielectric layer 555). For example, a probe area may be a portion of the dielectric layer 555 shown at block 51A in an area adjacent to the probe beam 504b, which is removed at block 52A. In some embodiments, the etching forms a cavity in the dielectric layer 555. In some embodiments, the cavity may be filled with a flexible material. In some embodiments, additional portions of dielectric layer 555 (e.g., to the left of probe stand 504° C.) may be concurrently or subsequently removed from the dielectric layer 555 (e.g., similar to removal of portion R2 at block 21B of FIG. 2B). The structure formed at block 52A may be referred to as the probe wafer.

FIG. 5B shows an example method of manufacturing a probe, in accordance with some embodiments of the present disclosure. FIG. 5B shows a probe tip 504A formed in a substrate 585, a probe beam 504B formed in a first dielectric layer 586 deposited on the substrate 585, and a probe stand 504C formed in a second dielectric layer 587 formed on the first dielectric layer 586. The probe tip 504A, probe beam 504B, and probe stand 504C may be formed using any suitable conductive materials, such as those described in the present disclosure. In some embodiments, the probe tip 504A, probe beam 504B, and/or probe stand 504C comprises a 3D printed metal, metal alloy or metal composite. In some embodiments, the probe tip 504A, probe beam 504B, or both comprises a 3D printed layer and a metal plating material. In some embodiments, the probe tip 504A, the probe beam 504B, probe stand 504C, or any combination thereof comprises a 3D printed layer and a metal plating material. In some embodiments, the probe tip 504A may be formed by filling the cavity in the substrate 585 with a suitable conductor by 3D printing method (e.g., applying a 3D print method to the example method of FIG. 5B or any suitable method such as those mentioned in the present disclosure). The formed structure may be planarized by CMP method prior to coating dielectric layer 586 over substrate 585. Dielectric layer 586 may be patterned to form the cavity for the probe beam 504B. The probe beam 504B may be formed by filling the cavity in the substrate 585 (e.g., a cavity in dielectric layer 586) with a suitable conductor by 3D printing method. The formed structure may be planarized by CMP method prior to coating dielectric layer 587 over dielectric 586. A similar etch, fill, and planarization method may be used to form the probe base (e.g., probe stand 504C) in FIG. 5B. In some embodiments, the probe tip 504A, probe beam 504B, and the probe base (e.g., probe stand 504C) may be formed by a method comprising barrier layer coating, conductive layer electroplating and 3D printing methods. In some embodiments, the probe beam and probe stand comprising a conductive layer (e.g., probe beam 504B and probe stand 504C of FIG. 5A) may connect the probe tip to conductive features in the substrate (e.g., probe beam 104B and probe stand 104C connecting the probe tip 104A to conductive feature 110 in substrate 106 in FIG. 1A). In some embodiments, the conductive layer may be an embedded conductive layer. For example, a 3D print method may be applied to example method in FIG. 2C comprising probe beam 204B and probe stand 204C, and in some embodiments, blocks 23-25 may be applied to forming a probe tip 104A in place of the probe tip 204A to be used at block 26 in FIG. 2C. An embedded conductive layer may comprise the probe beam 204B and probe stand 204C embedded in another material (e.g., plated with a conductive material, conductive plating material, or conductive layer 806 of FIGS. 8A-8B as applied to the probe beam 204B and probe stand 204° C.).

Prior to block 50B, a cavity for a probe tip 504A is created in a substrate 585. At block 50B, a probe tip 504A is formed in substrate 585. For example, an opening may be etched in silicon (e.g., substrate 585), and the opening may be filled with metal or any suitable conductive material as described in the present disclosure.

At block 51B, a first dielectric layer 586 is formed on the substrate 585, and a probe beam 504B is formed in the first dielectric layer on the substrate 585. The first dielectric layer 586 may comprise any suitable dielectric material (e.g., oxide), such as those described in the present disclosure. In some embodiments, the probe beam 504B is bonded to the probe tip 504A (e.g., DBI). In some embodiments the probe stand 504C in the second dielectric layer 587 is bonded (e.g., directly bonded, hybrid bonded) to the probe beam 504B of the first dielectric layer 586 (e.g., DBI)

At block 52B, a second dielectric layer 587 is formed on the first dielectric layer 586, and a probe stand 504C is formed in the second dielectric layer 586. The second dielectric layer 587 may comprise any suitable dielectric material, such as those described in the present disclosure.

In some embodiments, the method further includes forming a cavity around a probe area. For example, the method may include etching portions of the first and second dielectric layer 586 and 587 from a probe area (e.g., portions adjacent to a probe beam 504B). The etching may form a cavity in the first and second dielectric layer 586 and 587. For example, at block 53 a cavity is formed around the probe beam 504B. The method may include pattering the first dielectric layer 586 to form portions 586A and 586B, and patterning the second dielectric layer to form portions 587A and 587B. The patterned portions of the first dielectric layer 586 (e.g., portion 586A and portion 586B) and patterned portion of the second dielectric layer 587 (e.g., portion 587B) may define the cavity. In some embodiments, the cavity may be filled with a flexible material. The structure formed at block 53 may be referred to as a probe wafer.

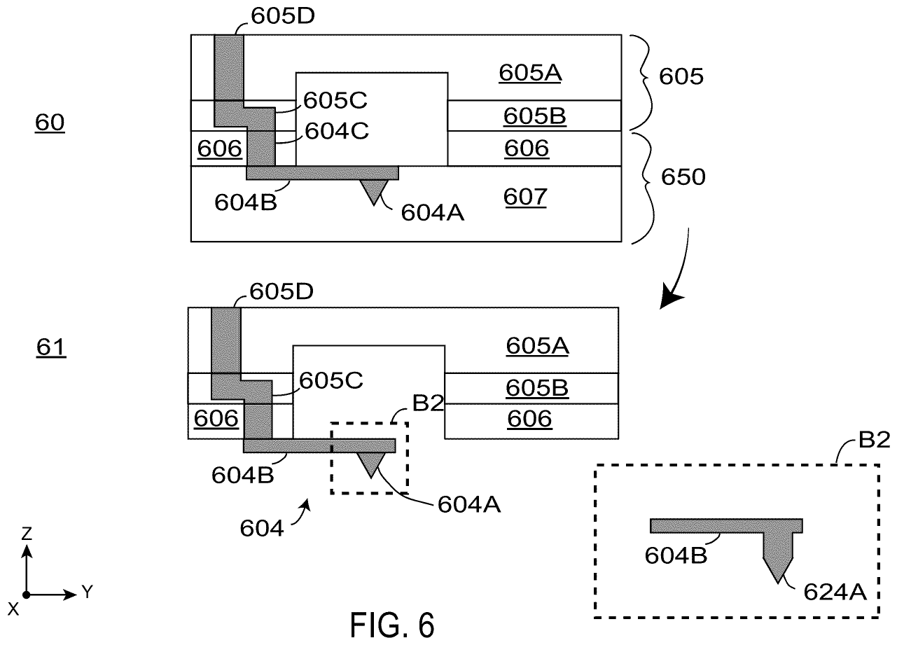

FIG. 6 shows an example method of manufacturing a probe, in accordance with some embodiments of the present disclosure. The method may include bonding a probe wafer 650 having a first cavity to a third substrate 605 (e.g., translator structure) having a second cavity. The first cavity of wafer 650 is proximate to the probe beam 604B and the first cavity may be formed by removing a portion of the dielectric layer 606 of the probe wafer 650 (e.g., on substrate 607). In some embodiments, the probe wafer may not have a cavity.

At block 60, the method may include bonding probe wafer 650 to a substrate 605 (e.g., translator structure, interposer structure). The bonding may comprise directly bonding or hybrid bonding the probe wafer 650 to the substrate 605.

In some embodiments, the probe wafer 650 may correspond to the probe wafer at block 52A of FIG. 5A. For example, substrate 607, patterned dielectric layer 606, probe tip 604A, probe beam 604B, and probe stand 604C may correspond to (e.g., be similar to or the same as) substrate 505, portions of the dielectric layer (e.g., support structure 555A and portion 555B of the dielectric layer 555), and probe tip 504A, probe beam 504B, and probe stand 504C. In some embodiments, the substrate 605 comprises of organic material (e.g., PI). In some embodiments, the substrate 607 comprising the probe beam 604B and probe tip 604A is a single layer (e.g., probe tip 504A and probe beam 504B in substrate 505 at block 50A). In other embodiments, the probe tip 604A is in a first layer of the first substrate 607 and the probe beam 604B is in a second layer of the first substrate 607 (e.g., probe tip 504A in substrate 585 and probe beam 504B in dielectric layer 586 at block 51B).

In some embodiments, the substrate 605 (e.g., translator structure, interposer structure) may comprise a material layer 605A and a redistribution layer 605B (e.g., interconnect layer). A cavity may be formed in at least part of the material layer 605A and redistribution layer 605B. In some embodiments, there may be no cavity in the substrate 605.

In some embodiments, the probe connector 605C in the substrate 605 is bonded to the probe stand 604C in the patterned dielectric layer 606. The probe connector 605C may electrically connect the probe 604 to components of a translator (e.g., control device, power, ground) or a prober through a conductive via 605D formed in a material layer 605A.

At block 61, the method includes removing the substrate 607. For example, the substrate 607 may be silicon, and the method includes wet etching the silicon to completely remove the silicon substrate. In some embodiments, the substrate 607 may be removed by dry etch or dry or wet laser ablation methods The cavity in the patterned dielectric layer 606 and the cavity in the probe wafer 650 together form a larger cavity allowing for the cantilever probe to bend, deflect, or enter into the cavity when force is applied (e.g., pressure from applying a die). In some embodiments, as illustrated in the example dotted boxed line B2, the probe tip 604A may be an elongated probe tip 624A. For example, a probe tip spacer may be inserted between the probe beam 604B and the probe tip 604A to form the elongated probe tip 624A. In some embodiment, the probe tip 624 may be fabricated separately and the attached to the probe beam 604A.

In some embodiments, a probe wafer resulting from a process of FIG. 5B at block 53 may be applied to the example method of FIG. 6. During the removal process at block 61, a silicon substrate may be removed (e.g., substrate 585 of FIG. 5B), and a portion of the dielectric layer (e.g., portions 586A and 586B) may remain in a same plane as the probe beam 504B. For example, a portion of the dielectric layer (e.g., portion 586A) may be to a left (e.g., and adjacent to, in direct contact with) of the probe beam 504B and a portion of the dielectric layer (e.g., portion 586B) may be to a right of a probe beam 504B (e.g., defining the cavity).

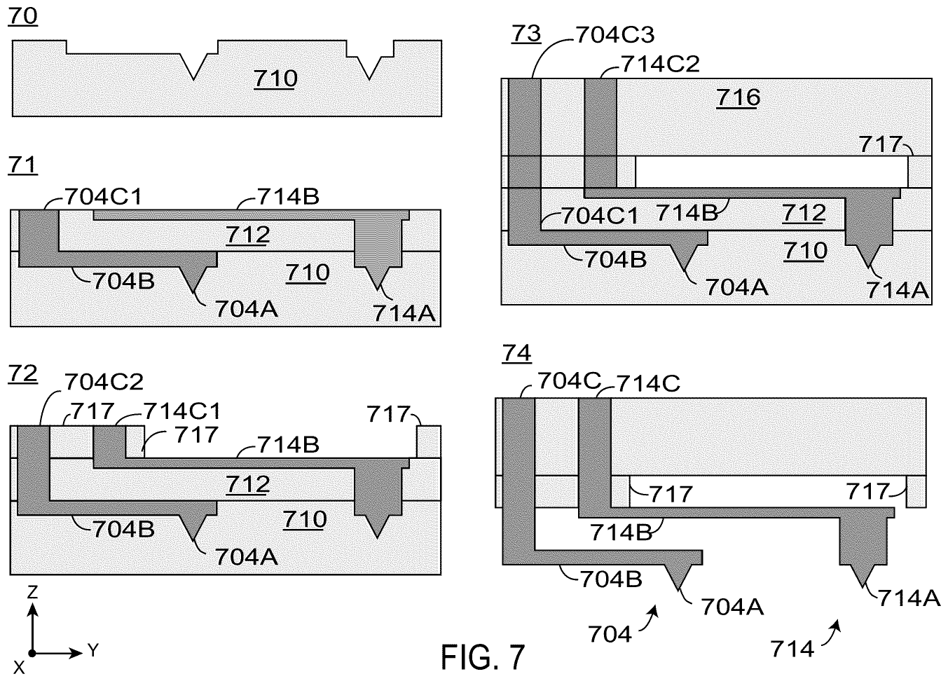

FIG. 7 shows an example of manufacturing a two-layer probe, in accordance with some embodiments of the present disclosure. At block 70, a method includes etching probe shapes into the substrate 710 (e.g., silicon). The etching probe shapes may include etching, into the substrate 710, a first and a second probe shape. The first probe shape may comprise etched cavities of a probe tip and a probe beam. The second probe shape may comprise etched cavities of a probe tip and a probe tip spacer. In some embodiments, the probe tip spacer may be larger in diameter or size of the probe tip. In some embodiments, the probe tip spacer may be a same diameter or size of the probe tip (e.g., elongated probe tip 624A of FIG. 6).

At block 71, the method includes adding a material layer 712 to substrate 710. In some embodiments, the method may include attaching a material layer 712 (e.g., substrate) to the substrate 710. For example, the material layer 712 may be bonded to substrate 710. The material layer 712 may comprise silicon material or engineering polymer. One or more vias (e.g., probe tip spacer, probe stand) and one or more lines or traces (e.g., beams) may be formed in the material layer 712. The material layer 712 may be attached to substrate 710 using direct bonding or direct hybrid bonding. In some embodiments, the method may include forming the material layer 712 on the substrate 710. For example, the method may include depositing a material layer 712 (e.g., comprising oxide material or engineering polymer) on a substrate 710. One or more vias (e.g., probe tip spacer, probe stand) and one or more lines or traces (e.g., beams) may be subsequently formed in the material layer 712.

In some embodiments, one or more vias (e.g., probe tip spacer, probe stand) and one or more lines or traces (e.g., beams) may be formed in the material layer 712 using a damascene process. For example, the method may include forming conductive vias or a probe tip spacer (e.g., portion between probe tip 714A and probe beam 714B) and a probe stand 704C1 (e.g., portion that may extend a height of a probe stand). The method may include forming conductive lines or traces or a probe beam 714B.

At block 72, the method includes forming a probe structure (e.g., probe wafer). For example, the method includes forming a patterned dielectric layer 717. The patterned dielectric layer 717 may comprise oxide or any suitable dielectric material as described in the present disclosure. Forming the patterned dielectric layer 717 may comprise adding or depositing a dielectric layer and etching a cavity in the dielectric layer. In some embodiments, a damascene process may be used to form the probe structure. For example, probe shapes (e.g., cavity, vias) may be formed in the dielectric layer, and filled with conductive material layer to form probe stand or probe stand 704C2 and probe stand 714C1.

At block 73, the method may include bonding the probe wafer formed at block 72 to a translator substrate 716. The bonding may comprise directly bonding or hybrid bonding the probe wafer to the translator substrate 716. The translator substrate 716 may comprise a redistribution layer (e.g., similar redistribution layer 605B of translator substrate 605 in FIG. 6) and a cavity. The translator substrate 716 may comprise an organic material. In some embodiments, the cavity may be optional. For example, there may be no cavity in the translator substrate 716. In some embodiments, the probe stands 704C3 and 714C2 disposed in the substrate 716 may be bonded to their respective probe stands (e.g., the probe stand 704C3 to the probe stand 704C2 of the first probe 704 and the probe stand 714C2 to the probe stand 714C1 of the second probe 714).

At block 74, the method may include etching a portion of the probe wafer (e.g., probe wafer formed at block 72). For example, the method may include wet etching a silicon portion of the probe wafer. In some embodiments, a silicon portion of the probe wafer may be removed by dry etch or dry or wet laser ablation methods. In some embodiments, the material layer 712 and substrate 710 comprise a silicon material, and material layer 712 and substrate 710 are completely removed. In some embodiments, the patterned dielectric layer 717 comprises a probe support that supports the probe stands for probe 704 and probe 714. In some embodiments, a taller probe tip (e.g., probe tip and probe tip spacers) may enable more travel without plateauing. A taller probe tip may include a probe tip spacer connecting a probe tip 714A to the probe beam 714B. For example, the probe 604 shown at block 61 in FIG. 6 may comprise a probe tip spacer (e.g., similar to the portion between 714A and 714B at block 74 in FIG. 7) between the probe beam 604B and the probe tip 604A for a taller probe tip 624A as shown in the dotted box B2. In some embodiments, the probes are plated with a metal (e.g., gold) as described in the present disclosure.

FIG. 8A shows an example method of forming a plated probe structure, in accordance with some embodiments of the present disclosure. The conductive material in the probe may comprise a plurality of conductive layers. For example, a conductive layer 806 may be a conductive plating layer and a conductive layer 810 may be a conductive fill layer. The conductive plating layer may be thinner than the conductive fill layer. The conductive plating layer may comprise a material that is more conductive than the conductive fill layer. The conductive fill layer may be a more robust or rigid structural material than the conductive plating layer. The example method shown in FIG. 8A may be applied to any of the embodiments of the present disclosure (e.g., any probe shown or described in the present disclosure as being formed with a single conductive material or layer may be formed to comprise multiple layers of conductive material).

At block 81, the method includes providing a substrate 805. The substrate 805 may comprise silicon material, dielectric material (e.g., oxide), and/or organic materials (e.g., PI). The method may include etching a probe shape (e.g., probe cavity, probe opening) into the substrate 805. In some embodiments, the probe shape includes a probe cavity or opening for a probe tip and a probe beam.

At block 82, the method includes forming a first conductive layer 806 in the probe cavity or opening. For example, the first conductive layer 806 may be a metal plating layer. The conductive layer 806 may comprise a metal plating material (e.g., gold, copper, or any suitable conductive material such as those mentioned in the present disclosure).

At block 83, the method includes forming a conductive layer 810 on the conductive layer 806. The conductive layer 810 may be a metal fill layer. The metal fill layer may comprise a metal fill material (e.g., copper (Cu), nickel (Ni), any suitable conductive material such as those mentioned in the present disclosure, or some combination of thereof). In some embodiments, a damascene process may be used to fill the probe cavity or opening. Filling the probe cavity creates the probe tip and the probe beam. In some embodiments, the probe cavity is filled with multiple metal layers (e.g., Cu—Ni—Cu) or alloy metal or alloy metal laminate. In some embodiments, the conductive layer 806 and the metal fill layer may be formed by 3D printing methods.

In some embodiments, the method includes adding a probe stand (e.g., post) to the probe structure (e.g., similar to block 51A in FIG. 5A). For example, the method includes adding a dielectric layer (e.g., oxide layer), etching the oxide to form a cavity or via, and filling the cavity or via with a conductive layer to form the probe stand of the probe structure. In some embodiments, a damascene process may be used to form the probe stand (e.g., post).

In some embodiments, the method includes etching the dielectric layer (e.g., oxide) from a probe area (e.g., similar to block 52A of FIG. 5A). For example, the etching forms a cavity in the dielectric layer in a probe area (e.g., area that a probe beam may deflect into). In some embodiments, the cavity may be filled with a flexible material. The structure formed may be referred to as the probe wafer.

In some embodiments, the method includes bonding probe wafer to the translator structure. The translator structure may comprise a redistribution layer (RDL) and a cavity. The bonding may comprise directly bonding or hybrid bonding the probe wafer to the translator structure. In some embodiments, the cavity may be optional. For example, there may be no cavity in the translator structure.

In some embodiments, the method includes etching a portion of the probe wafer. For example, the method may include wet etching the silicon portion of the probe wafer. In some embodiments, the a silicon portion of the probe wafer may be removed by dry etch or dry or wet laser ablation methods The method may include gold plating the tip of the probe structure.

In some embodiments, a method may include filling the probe cavity with a metal fill layer and may include plating the probe tip and/or probe beam after it is formed. For example, at block 81, the method includes filling the probe opening or cavity with a metal fill layer (e.g., conductive layer 810) without metal plating layer (e.g., conductive layer 806).

FIG. 8B shows an example method of forming a plated probe structure, in accordance with some embodiments of the present disclosure. The substrate 815 may comprise silicon material. Blocks 87-8 may include similar features or components to blocks 82-83 described above, and therefore the description of similar features is omitted for brevity.

At block 85, the method may include etching a probe shape (e.g., probe cavity, probe opening) into the substrate 815 (e.g., silicon). In some embodiments, the probe shape includes an opening or a cavity for a probe tip.

At block 86, the method may include filling the probe cavity with conductive layer 812 (e.g., metal fill material or any suitable conductive material such as those mentioned in the present disclosure). In some embodiments, conductive layer 812 comprises a same conductive material as the metal layer 810. In some embodiments, conductive layer 812 comprises a different conductive material as the metal layer 810.

At block 87, the method may include depositing a material layer (e.g., oxide), forming an opening in the material layer (e.g., probe shape corresponding to a probe beam), and depositing a conductive plating layer (e.g., conductive layer 806) in the opening. The method further includes depositing a conductive fill layer (e.g., conductive layer 810) on the conductive plating layer (e.g., conductive layer 806) in the opening. The method further includes depositing a conductive plating layer (e.g., conductive layer 806) on the conductive fill layer (e.g., conductive layer 810).

At block 88, the method further comprises attaching the probe beam and probe tip to a probe stand 807, and plating the tip with a conductive layer 808 (e.g., metal plating material). In some embodiments, the conductive layer 808 comprises a same conductive material as the metal layer 806. In some embodiments, the conductive layer 808 comprises a different conductive material as the metal layer 806.

FIG. 9 schematically illustrates an example method of forming a probe card, in accordance with some embodiments of the present disclosure. Although one probe 904 is shown, the method may be applied to forming any suitable number of probes.

At block 90, the method includes providing a first substrate 905. In some embodiments, the substrate 905 corresponds to (e.g., is similar to or same as) the substrate 815 or substrate 585. Providing the substrate 905 may include forming a probe tip 904A in the substrate 905. In some embodiments, the substrate 905 comprises the probe tip 904A and probe beam 904B disposed in a silicon material. The method may further comprise providing a substrate 903. The second substrate 903 may comprise an oxide material and/or an organic material. Providing the substrate 903 may comprise forming a probe beam 904B and probe stand 904C in the substrate 903. For example, a probe beam and a probe stand may be formed in a substrate using a similar method to that shown at blocks 20C-22C in FIG. 2C. The method further includes attaching the probe tip 904A to the probe beam 904B. For example, the method includes bonding (e.g., directly bonding, directly hybrid bonding, DBI bonding) the substrate 905 and the substrate 903 to form a workpiece 909 (e.g., as shown in block 91). In some embodiments, the substrate 905 is directly bonded to the substrate 903. In some embodiments, the substrate 905 is directly hybrid bonded to the substrate 903.

In some embodiments, the substrates 905 and 903 comprise a same material (e.g., silicon). In some embodiments, the substrates 905 and 903 comprise different materials. For example, the substrate 905 may comprise silicon while the substrate 903 may comprises an organic material (e.g., polyimide). In some embodiments, substrate 903 may comprise a dielectric material (e.g., oxide).

In some embodiments, the substrate 903 may comprise two substrates or layers. For example, a first substrate may comprise the probe beam 904B, and a second substrate may comprise the probe stand 904C. The first substrate may be bonded (e.g., directly bonded, hybrid bonded) to the second substrate.

At block 91, the workpiece 909 is directly bonded to a third substrate 906. In some embodiments, the workpiece is directly bonded or hybrid bonded to the third substrate 906. In some embodiments, the third substrate 906 is an interposer. In some embodiments, the third substrate 906 is a translator. In some embodiments, the probe stand 904C is bonded to a bonding pad 910. In some embodiments, the bonding pad 910 is a conductive feature comprising metal. In some embodiments the bonding pad 910 may comprise a same or similar material as the conductive materials used to form the probe structure 904.

At block 92, the method includes removing the first substrate 905 and the second substrate 903 are removed. The method may include completely removing the first substrate 905 and the second substrate 903. For example, the first substrate and the second substrate 903 and 905 may comprise a silicon material, and the first and second substrates 903 and 905 may be removed by wet etching the silicon. In some embodiments, the first and second substrates 903 and 905 may be removed by dry etch or dry or wet laser ablation methods In some embodiments, the first substrate 905 is completely removed, and portions of the second substrate 903 is removed (e.g., portions of second substrate 903 surrounding the probe stand 904C may remain to provide structural support for the probe stand of FIG. 2B).

In some embodiments, the probe structure 904 (e.g., probe tip, probe beam, and probe stand) 904 may be formed in a silicon or inorganic material. In some embodiments, the probe tip 904A is formed in silicon (e.g., a first substrate 905), and probe beam 904B and probe stand 904C are formed in an organic layer (e.g., second substrate 903). The organic layer may comprise a PI material. DBI bonding can occur between organic or inorganic material.

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 1008a and/or 1008b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Ser. No. 63/524,564 , filed Jun. 30, 2023, and U.S. Ser. No. 18/391,173 , filed Dec. 20, 2023, the entire contents of each of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

FIGS. 10A and 10B schematically illustrate cross-sectional side views of first and second elements 1002, 1004 prior to and after, respectively, a process for forming a directly bonded structure, and more particularly a hybrid bonded structure, according to some embodiments. In FIG. 10B, a bonded structure 1000 comprises the first and second elements 1002 and 1004 that are directly bonded to one another at a bond interface 1018 without an intervening adhesive. Conductive features 1006a of a first element 1002 may be electrically connected to corresponding conductive features 1006b of a second element 1004. In the illustrated hybrid bonded structure 1000, the conductive features 1006a are directly bonded to the corresponding conductive features 1006b without intervening solder or conductive adhesive.

The conductive features 1006a and 1006b of the illustrated embodiment are embedded in, and can be considered part of, a first bonding layer 1008a of the first element 1002 and a second bonding layer 1008b of the second element 1004, respectively. Field regions of the bonding layers 1008a, 1008b extend between and partially or fully surround the conductive features 1006a, 1006b. The bonding layers 1008a, 1008b can comprise layers of non-conductive materials suitable for direct bonding, as described above, and the field regions are directly bonded to one another without an adhesive. The non-conductive bonding layers 1008a, 1008b can be disposed on respective front sides 1014a, 1014b of base substrate portions 1010a, 1010b.

The first and second elements 1002, 1004 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 1002, 1004, and back-end-of-line (BEOL) interconnect layers over such semiconductor portions. The bonding layers 1008a, 1008b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 1010a, 1010b, and can electrically communicate with at least some of the conductive features 1006a, 1006b. Active devices and/or circuitry can be disposed at or near the front sides 1014a, 1014b of the base substrate portions 1010a, 1010b, and/or at or near opposite backsides 1016a, 1016b of the base substrate portions 1010a, 1010b. In other embodiments, the base substrate portions 1010a, 1010b may not include active circuitry, but may instead comprise dummy substrates, passive interposers, passive optical elements (e.g., glass substrates, gratings, lenses), etc. The bonding layers 1008a, 1008b are shown as being provided on the front sides of the elements, but similar bonding layers can be additionally or alternatively provided on the back sides of the elements.

In some embodiments, the base substrate portions 1010a, 1010b can have significantly different coefficients of thermal expansion (CTEs), and bonding elements that include such different based substrate portions can form a heterogenous bonded structure. The CTE difference between the base substrate portions 1010a and 1010b, and particularly between bulk semiconductor (typically single crystal) portions of the base substrate portions 1010a, 1010b, can be greater than 5 ppm/° C. or greater than 10 ppm/° C. For example, the CTE difference between the base substrate portions 110a and 110b can be in a range of 5 ppm/° C. to 100 ppm/° C., 5 ppm/° C. to 40 ppm/°C, 10 ppm/° C. to 100 ppm/° C., or 10 ppm/° C. to 40 ppm/° C.

In some embodiments, one of the base substrate portions 110a, 110b can comprise optoelectronic single crystal materials, including perovskite materials, that are useful for optical piezoelectric or pyroelectric applications, and the other of the base substrate portions 1010a, 1010b comprises a more conventional substrate material. For example, one of the base substrate portions 1010a, 1010b comprises lithium tantalate (LiTaO₃) or lithium niobate (LiNbO₃), and the other one of the base substrate portions 1010a, 1010b comprises silicon (Si), quartz, fused silica glass, sapphire, or a glass. In other embodiments, one of the base substrate portions 1010a, 1010b comprises a III-V single semiconductor material, such as gallium arsenide (GaAs) or gallium nitride (GaN), and the other one of the base substrate portions 1010a, 1010b can comprise a non-III-V semiconductor material, such as silicon (Si), or can comprise other materials with similar CTE, such as quartz, fused silica glass, sapphire, or a glass. In still other embodiments, one of the base substrate portions 1010a, 1010b comprises a semiconductor material and the other of the base substrate portions 1010a, 1010b comprises a packaging material, such as a glass, organic or ceramic substrate.

In some arrangements, the first element 1002 can comprise a singulated element, such as a singulated integrated device die. In other arrangements, the first element 1002 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 1004 can comprise a singulated element, such as a singulated integrated device die. In other arrangements, the second element 1004 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 1002, 1004 are shown, any suitable number of elements can be stacked in the bonded structure 1000. For example, a third element (not shown) can be stacked on the second element 1004, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 1002. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 1008a, 1008b, the bonding layers 1008a, 1008b can be prepared for direct bonding. Non-conductive bonding surfaces 1012a, 1012b at the upper or exterior surfaces of the bonding layers 1008a, 1008b can be prepared for direct bonding by polishing, for example, by chemical mechanical polishing (CMP). The roughness of the polished bonding surfaces 1012a, 1012b can be less than 30 Å rms. For example, the roughness of the bonding surfaces 1012a and 1012b can be in a range of about 0.1 Å rms to 15 Å rms, 0.5 Å rms to 10 Å rms, or 1 Å rms to 5 Å rms. Polishing can also be tuned to leave the conductive features 1006a, 1006b recessed relative to the field regions of the bonding layers 1008a, 1008b.

Preparation for direct bonding can also include cleaning and exposing one or both of the bonding surfaces 1012a, 1012b to a plasma and/or etchants to activate at least one of the surfaces 1012a, 1012b. In some embodiments, one or both of the surfaces 1012a, 1012b can be terminated with a species after activation or during activation (e.g., during the plasma and/or etch processes). Without being limited by theory, in some embodiments, the activation process can be performed to break chemical bonds at the bonding surface(s) 1012a, 1012b, and the termination process can provide additional chemical species at the bonding surface(s) 1012a, 1012b that alters the chemical bond and/or improves the bonding energy during direct bonding. In some embodiments, the activation and termination are provided in the same step, e.g., a plasma to activate and terminate the surface(s) 1012a, 1012b. In other embodiments, one or both of the bonding surfaces 1012a, 1012b can be terminated in a separate treatment to provide the additional species for direct bonding. In various embodiments, the terminating species can comprise nitrogen. For example, in some embodiments, the bonding surface(s) 1012a, 1012b can be exposed to a nitrogen-containing plasma. Other terminating species can be suitable for improving bonding energy, depending upon the materials of the bonding surfaces 1012a, 1012b. Further, in some embodiments, the bonding surface(s) 1012a, 1012b can be exposed to fluorine. For example, there may be one or multiple fluorine concentration peaks at or near a bond interface 1018 between the first and second elements 1002, 1004. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 1000, the bond interface 1018 between two non-conductive materials (e.g., the bonding layers 1008a, 1008b) can comprise a very smooth interface with higher nitrogen (or other terminating species) content and/or fluorine concentration peaks at the bond interface 1018. In some embodiments, the nitrogen and/or fluorine concentration peaks may be detected using various types of inspection techniques, such as SIMS techniques. The polished bonding surfaces 1012a and 1012b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 1008a and 1008b can be directly bonded to one another without an adhesive. In some embodiments, the elements 1002, 1004 are brought together at room temperature, without the need for application of a voltage, and without the need for application of external pressure or force beyond that used to initiate contact between the two elements 1002, 1004. Contact alone can cause direct bonding between the non-conductive surfaces of the bonding layers 1008a, 1008b (e.g., covalent dielectric bonding). Subsequent annealing of the bonded structure 1000 can cause the conductive features 1006a, 1006b to directly bond.

In some embodiments, prior to direct bonding, the conductive features 1006a, 1006b are recessed relative to the surrounding field regions, such that a total gap between opposing contacts after dielectric bonding and prior to anneal is less than 15 nm, or less than 10 nm. Because the recess depths for the conductive features 1006a and 1006b can vary across each element, due to process variation, the noted gap can represent a maximum or an average gap between corresponding conductive features 1006a, 1006b of two joined elements (prior to anneal). Upon annealing, the conductive features 1006a and 1006b can expand and contact one another to form a metal-to-metal direct bond.

During annealing, the conductive features 1006a, 1006b (e.g., metallic material) can expand while the direct bonds between surrounding non-conductive materials of the bonding layers 1008a, 1008b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials'melting temperature, such that bonds can form with lower anneal temperatures compared to soldering or thermocompression bonding.

In various embodiments, the conductive features 1006a, 1006b can comprise discrete pads, contacts, electrodes, or traces at least partially embedded in the non-conductive field regions of the bonding layers 1008a, 1008b. In some embodiments, the conductive features 1006a, 1006b can comprise exposed contact surfaces of TSVs (e.g., through silicon vias).

As noted above, in some embodiments, in the elements 1002, 1004 of FIG. 10A prior to direct bonding, portions of the respective conductive features 1006a and 1006b can be recessed below the non-conductive bonding surfaces 1012a and 1012b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 1006a, 1006b or to average depths of the recesses relative to local non-conductive field regions. Even for an individual conductive feature 1006a, 1006b, the vertical recess can vary across the feature, and so can be measured at or near the lateral middle or center of the cavity in which a given conductive feature 1006a, 1006b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 1006a, 1006b across the direct bond interface 1018 (e.g., small or fine pitches for regular arrays).

In some embodiments, a pitch p of the conductive features 1006a, 1006b, such as conductive traces embedded in the bonding surface of one of the bonded elements, may be less than 40 μm, less than 20 μm, less than 10 μm, less than 5 μm, less than 2 μm, or even less than 1 um. For some applications, the ratio of the pitch of the conductive features 1006a and 1006b to one of the lateral dimensions (e.g., a diameter) of the bonding pad is less than is less than 20, or less than 10, or less than 5, or less than 3 and sometimes desirably less than 2. In various embodiments, the conductive features 1006a and 1006b and/or traces can comprise copper or copper alloys, although other metals may be suitable, such as nickel, aluminum, or alloys thereof. The conductive features disclosed herein, such as the conductive features 1006a and 1006b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 1002, 1004, as shown, the orientations of one or more conductive features 1006a, 1006b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 1006b in the bonding layer 1008b (and/or at least one internal conductive feature, such as a BEOL feature) of the upper element 1004 may be tapered or narrowed upwardly, away from the bonding surface 1012b. By way of contrast, at least one conductive feature 1006a in the bonding layer 1008a (and/or at least one internal conductive feature, such as a BEOL feature) of the lower element 1002 may be tapered or narrowed downwardly, away from the bonding surface 1012a. Similarly, any bonding layers (not shown) on the backsides 1016a, 1016b of the elements 1002, 1004 may taper or narrow away from the backsides, with an opposite taper orientation relative to front side conductive features 1006a, 1006b of the same element.

As described above, in an anneal phase of hybrid bonding, the conductive features 1006a, 1006b can expand and contact one another to form a metal-to-metal direct bond. In some embodiments, the materials of the conductive features 1006a, 1006b of opposite elements 1002, 1004 can interdiffuse during the annealing process. In some embodiments, metal grains grow into each other across the bond interface 1018. In some embodiments, the metal is or includes copper, which can have grains oriented along the 1011 crystal plane for improved copper diffusion across the bond interface 1018. In some embodiments, the conductive features 1006a and 1006b may include nanotwinned copper grain structure, which can aid in merging the conductive features during anneal. There is substantially no gap between the non-conductive bonding layers 1008a and 1008b at or near the bonded conductive features 1006a and 1006b. In some embodiments, a barrier layer may be provided under and/or laterally surrounding the conductive features 1006a and 1006b (e.g., which may include copper). In other embodiments, however, there may be no barrier layer under the conductive features 1006a and 1006b.

It is contemplated that any combination of the methods described above may be used to form the probe structures, probe cards, probe arrays, and/or probes, whether or not expressly recited herein.

The embodiments discussed above are intended to be illustrative and not limiting. One skilled in the art would appreciate that individual aspects of probe structures, probe cards, probe arrays, probes, and methods discussed herein may be omitted, modified, combined, and/or rearranged without departing from the scope of the disclosure.

1. A probe card comprising:
a probe comprising:
a probe tip extending in a first direction;
a probe beam extending in a second direction different than the first direction; and
a probe stand extending in the first direction; and
a substrate comprising a conductive feature disposed in a material layer, wherein the probe stand is directly bonded to the conductive feature of the substrate via direct metal bonds.

2. The probe card of claim 1, wherein:
the probe tip and the probe beam comprise a first metal fill layer;
the probe stand comprises a second metal fill layer; and
the probe beam is directly bonded to the probe stand via direct metal bonds.

3. The probe card of claim 1, wherein the probe stand is disposed in a silicon structure.

4. The probe card of claim 1, wherein:
the probe tip comprises a first metal fill layer;
the probe beam and the probe stand comprises a second metal fill layer; and
the probe tip is directly bonded to the probe beam via direct metal bonds.

5. The probe card of claim 1, wherein:
the probe card comprises a plurality of probes; and
a length of each probe beam of the plurality of probes is greater than a pitch of the plurality of probes in the probe card.

6. The probe card of claim 1, wherein:
the probe card comprises a plurality of probes; and
each probe beam is in a spiral shape from a top down view.

7. The probe card of claim 1, wherein the probe stand is disposed in an oxide structure.

8. The probe card of claim 1, wherein:
the probe stand is disposed in a patterned oxide layer; and
an opening in the patterned oxide layer defines a cavity that the probe beam can enter when deflected.

9. The probe card of claim 1, wherein:
the probe beam is disposed in a same plane as a first patterned oxide layer;
the probe stand is disposed in a second patterned oxide layer; and
an opening in the first patterned oxide layer and the second patterned oxide layer defines a cavity that the probe beam can enter when deflected.

10. The probe card of claim 1, wherein the substrate comprises a cavity that the probe beam can enter when deflected.

11. The probe card of claim 1, wherein the probe tip includes a probe tip spacer extending a distance of the probe tip to the probe beam.

12. The probe card of claim 11, wherein the probe tip spacer is less than about 10 microns in height.

13. The probe card of claim 1, wherein:
the probe card comprises a plurality of probes comprising first probes and second probes;
probe tips of the first probes and the probe tips of the second probes are substantially co-planar in a first plane;
probe beams of the first probes are substantially co-planar in a second plane different than the first plane; and
probe beams of the second probes are substantially co-planar in a third plane different than the first plane and the second plane.

14. The probe card of claim 1, wherein:
the probe card comprises a plurality of probes; and
the probe tips of the plurality of probes are substantially co-planar.

15-18. (canceled)

19. The probe card of claim 1, wherein the probe tip comprises a metal fill material and a metal plating material covering the metal fill material.

20. The probe card of claim 1, wherein the probe tip and the probe beam comprise a metal fill material and a metal plating material covering the metal fill material.

21. The probe card of claim 1, wherein the probe beam comprises a metal fill material and a metal plating material covering the metal fill material.

22-24. (canceled)

25. The probe card of claim 1, wherein the first direction is orthogonal to the second direction.

26. The probe card of claim 1, wherein the first direction is not orthogonal to the second direction.

27. A method of fabricating a probe card comprising:
providing one or more probes, each probe comprising a probe stand extending in a first direction, a probe beam extending in a second direction different than the first direction, and a probe tip extending in the first direction;
providing a probe card substrate comprising one or more conductive features disposed in a material layer; and
directly bonding each probe stand to a respective conductive feature.

28-51. (canceled)
